(19) United States
(12) Patent Application Publication
(10) Pub. No.: US 2021/0371967 A1
(43) Pub. Date: Dec. 2, 2021

(54) SELECTIVE DEPOSITION OF METALLIC LAYERS

(71) Applicant: The University of Warwick, Warwickshire (GB)

(72) Inventors: Silvia VARAGNOLO, Coventry (GB); Ross HATTON, Coventry (GB)

(73) Assignee: The University of Warwick, Warwickshire (GB)

(21) Appl. No.: 17/286,629

(22) PCT Filed: Oct. 21, 2019
(86) PCT No.: PCT/GB2019/052994

§ 371 Date: Apr. 19, 2021

(30) Foreign Application Priority Data
Oct. 19, 2018 (GB) 1817037.3

(51) Int. Cl. C23C 14/04; H01B 5/14; C23C 14/02; C23C 14/14; C23C 14/24; C23C 14/58

(52) U.S. Cl. CPC C23C 14/042; H01B 5/14; C23C 14/024; H01L 31/022491; C23C 14/24; C23C 14/584; C23C 14/14

(57) ABSTRACT

A method is described for selectively depositing a metallic layer (10) including one or more of copper, silver and gold. The method includes depositing a fluorinated layer (5) over a surface (1, 4). The fluorinated layer (5) has a thickness sufficient to substantially prevent deposition of the copper, silver and/or gold between the fluorinated layer (5) and the surface (1, 4) during a subsequent evaporation step using a given deposition rate. The method also includes forming the metallic layer (10) by evaporating, at the given deposition rate, the copper, silver and/or gold over the surface (1, 4) and the fluorinated layer (5). The copper, silver and/or gold preferentially adhere to the portions of the surface (1, 4) not covered by the fluorinated layer (s).

### FIELD OF THE INVENTION

The present invention relates to methods of forming selectively deposited metallic layers, and metallic layers produced using the methods.

### BACKGROUND

With the highest electrical conductivities amongst metals, copper, silver and gold, or alloys thereof, have been extensively used in the electronics and photovoltaics industries. Thin films of these metals can also be used for low emissivity glass for architectural applications. Thin films of these metals, sometimes referred to as “coinage” metals, patterned with millions of features per square centimetre have also attracted interest for a range of new applications including transparent and plasmon-active electrodes for emerging thin film photovoltaics, bleach resistance coloured coating for glass, elements for biological sensors, interconnects and electrodes for organic transistors, as a platform for the nascent field of plasmonic nano-chemistry and for the study of extraordinary optical and infra-red transmission.

Whilst conventional photolithography and laser interferometry offer a means of fabricating such patterned metal films, they involve a metal etching step which incurs considerable economic and environmental cost due to metal wastage and the chemicals used for metal etching. Additionally, these conventional techniques are poorly compatible with rapid roll-to-roll processing, which is limiting for emerging large area low-cost applications such as organic and perovskite photovoltaics. The research scale methods of electron-beam lithography, focused ion beam milling and dip-pen nanolithography quickly become prohibitively expensive when scaling to large numbers of individual substrates or to macroscopic areas. Whilst nanosphere lithographic methods are simple to implement for the fabrication of a periodic array of metal structures, the geometries that can be achieved are very limited and a metal lift-off step is needed.

Due to the industrial importance of the metallisation of insulating substrates a great deal of effort has been directed at improving adhesion between evaporated metal films and glass and polymer substrates. As well as imparting mechanical robustness, improved adhesion between the metal and the supporting substrate enables the formation of slab-like films of copper, silver or gold at thickness less than 10 nm (<80 atoms) which is otherwise difficult to achieve due to the high surface energy of these metals, which is a powerful driver for them to form isolated nanoparticles at low metal coverage. Studies pertaining to the very early stage metal nucleation and growth of copper and silver on plastic substrates have shown that whilst all metal atoms are initially adsorbed, the proportion that actually remain on the surface can vary greatly between polymers, although these studies have been limited to metal thickness equivalent to 1-2 metal atoms and extremely low metal deposition rates (˜10-2 Angstroms per second). The proportion of metal that remains on the surface can be quantified in terms of a condensation coefficient C, which depends strongly on the nominal metal coverage. Previously, there has been a great deal of effort directed at maximising the condensation coefficient C.

In relation to selective deposition of metals deposited by thermal evaporation, Tsujioka, “Selective metal deposition on organic surfaces for device applications”, J. Mater. Chem. C, 2014, 2, 221, describes selective deposition of Zn, Mg, Pb, Ca, Mn, Sn, Al, Ga, on different polymers.

GB 2429841 A describes that patterned thin film layers may be applied to a substrate surface by masking selective areas of a substrate surface, e.g. with a printed pattern of a deposition inhibiting material such as an oil, and vapor-deposited thin film material.

### SUMMARY

According to a first aspect of the invention, there is provided a method of selectively depositing a metallic layer comprising one or more of copper, silver and gold. The method includes depositing a fluorinated layer over a surface. The fluorinated layer has a thickness sufficient to substantially prevent deposition of the copper, silver and/or gold between the fluorinated layer and the surface during a subsequent evaporation step using a given deposition rate. The method also includes forming the metallic layer by evaporating, at the given deposition rate, the copper, silver and/or gold over the surface and the fluorinated layer. The copper, silver and/or gold preferentially adhere to the portions of the surface not covered by the fluorinated layer.

The portions of the surface not covered by the fluorinated layer are the portions left exposed by the fluorinated layer. Evaporation may be conducted in vacuum, and may include thermal, electron beam, resistive or flash evaporation. The portions of the surface covered by the fluorinated layer may be free, or substantially free, of copper, silver and/or gold. The rate of deposition of copper, silver and/or gold on or over the portions of the surface not covered (i.e. left exposed) by the fluorinated layer may be at least five times, or at least ten times higher than the rate of deposition of copper, silver and/or gold over or on the portions of the surface covered by the fluorinated layer. The mass per unit area of copper, silver and/or gold deposited on the portions of the surface covered not covered by the fluorinated layer may be at least 5 times, at least 10 times, at least 20 times, or at least 100 times greater than the mass per unit area of copper, silver and/or gold deposited on or over the fluorinated layer, or between the fluorinated layer and the surface.

The metallic layer may consist of any one of copper, gold, or silver. The metallic layer may consist of an alloy of copper and silver. The metallic layer may consist of an alloy of copper and gold. The metallic layer may consist of an alloy of gold and silver. The metallic layer may consist of an alloy of copper, silver and gold. The surface may be a surface of a substrate which includes or is formed of glass. The surface may be a surface of a substrate which includes or is formed of a polymer material. The surface may be a surface of a substrate which includes or is formed of an organic or inorganic semiconductor. The surface may be a surface of a substrate which includes or is formed of an electrically insulating material. The substrate may be transparent. The substrate may be opaque. The surface may be a layer of an electronic device. The electronic device may be a photovoltaic device or an organic photovoltaic device. The electronic device may be a light emitting diode or an organic light emitting diode. The electronic device may be a sensor. Thin films of copper, silver and/or gold may be deposited with controllable transmissivity and reflectivity on glass substrates, for use as low emissivity glass for architectural applications.

The fluorinated layer may be deposited as a negative image of a pattern, such that the metallic layer is selectively deposited according to the pattern. The pattern may take the form of a regular array of features. The pattern may include a circuit pattern or a part of a circuit pattern.

The fluorinated layer may be deposited by applying droplets of a fluorinated compound to the surface until a fraction of the surface covered by the fluorinated layer is equal or approximately equal to a predetermined fraction. The fluorinated compound may be an ink. The droplets of the fluorinated compound may have a known size distribution. The droplets of the fluorinated compound may be applied to the surface for a pre-calibrated duration. The predetermined fraction may be determined based on a desired reflectance and/or transmittance of the metallic layer.

The fluorinated layer may be deposited by dewetting of a continuous layer to form a fluorinated layer in the form of randomly distributed islands. The randomly distributed islands may be cured and/or allowed to dry to form the fluorinated layer. A continuous layer for dewetting may be formed using any suitable method such as, for example, printing, spraying, rolling and so forth. Dewetting may be performed by heating the continuous layer. Dewetting may be performed by exposing the continuous layer to a solvent.

The method may also include a washing process to remove the fluorinated layer without removing the metallic layer. The washing process may include using a solution of a chemical substance that can dissolve or detach the fluorinated layer. The washing process may include rinsing with tetrabutylammonium fluoride/tetrahydrofuran solution. The washing process may include rinsing with an acid solution such as, for example, hydrochloric acid (HCl). The washing process may include washing with a solvent such as, for example, water, acetone, dimethylacetamide or hydrofluoroether. The washing process may include washing with the same solvent or solvents used to deposit the fluorinated layer.

The surface may correspond to a substrate which is pre-coated with an adhesion layer, and the metallic layer and the fluorinated layer may be deposited over the adhesion layer. The surface may correspond to a substrate, and the method may also include coating the surface with an adhesion layer, prior to depositing the fluorinated layer and metallic layer over the adhesion layer. A substrate may be transparent or opaque.

The adhesion layer may include or be formed from a metal such as, for example, nickel, chromium, germanium or gold. The adhesion layer may include or be formed from an inorganic compound such as some metal oxides, for example molybdenum oxide or titanium dioxide. The adhesion layer may be an organic material such as 3-mercaptopropyltrimethoxysilane or 3-aminopropyltrimethoxysilane. The adhesion layer may be a polymeric material such as polyethylenimine, polyallylamine or hybrids thereof. The washing process may include washing with one or more solvents and/or solutions of chemical substances which dissolve or detach the adhesion layer on portions of the surface which are not covered by the metallic layer. The adhesion layer may include or be formed from any material, compound, alloy or mixture which has a relatively larger condensation coefficient C for the copper, silver and/or gold than a substrate providing the surface. Additionally or alternatively, the adhesion layer may modify the wetting and/or adherence properties of the fluorinated layer.

The fluorinated layer may consist of or include a fluorinated polymer. The fluorinated layer may consist of or include a fluorinated non-polymeric molecule. The fluorinated layer may consist of or include any highly fluorinated organic molecule or polymer. Highly fluorinated may mean that 50% or more of carbon-hydrogen bonds in an organic molecule or polymer are substituted by carbon-fluorine bonds. The fluorinated layer may consist of or include any highly fluorinated hydrocarbon. The fluorinated layer may consist of or include any perfluorocarbon (i.e. a molecule or polymer containing just carbon and fluorine). The fluorinated layer may consist of or include any perfluorinated compounds. The fluorinated layer may consist of or include a mixture of highly fluorinated molecules or polymers. The fluorinated layer may consist of or include trichloro(1H,1H,2H,2H-perfluorooctyl)silane (FTS) or 1H,1H,2H,2H-perfluorododecyltrichlorosilane or 1H,1H,2H,2H-perfluorodecyltriethoxysilane or 1H,1H,2H,2H-Perfluorooctyltriethoxysilane. The fluorinated layer may consist of or include poly(vinylidene fluoride-co-hexafluoropropylene) (PVDF-HFP, (—CH₂CF₂-)ₓ[—CF₂CF(CF₃)—]_{y}), poly(vinylidene fluoride), poly(tetrafluoroethylene), poly(chlorotrifluoroethylene) or perfluoropolymer, P(TTD-TFE), poly(tetrafluoroethylene-co-2,2,4-trifluoro-5-trifluoromethoxy-1,3-dioxole).

Depositing the fluorinated layer may include printing, spray-deposition or dip-coating. Printing may include micro-contact printing. Printing may include ink-jet printing, gravure printing, flexographic printing, and so forth.

The method may include forming the metallic layer to an optically transparent thickness. An optically transparent thickness may mean that the metallic layer does not exceed an optical skin depth. A metallic layer may be optically transparent when it has a thickness of less than or equal to 15 nm. A metallic layer may be optically transparent when it has a thickness of between 15 nm and 85 nm. A metallic layer may be optically transparent when it transmits more than 50%, more than 75%, more than 80%, more than 90% or more than 95% of incident light.

The method may include forming the metallic layer to an optically opaque thickness. An optically opaque thickness may mean that the metallic layer equals or exceeds an optical skin depth. A metallic layer may be optically opaque when it has a thickness of greater than or equal to 85 nm. A metallic layer may be optically opaque when it transmits less than 50%, less than 25%, less than 10% or less than 5% of incident light.

The metallic layer may take the form of a transparent mesh. A transparent mesh may be formed from a metallic layer deposited to an optically transparent thickness. A transparent mesh may be formed from a metallic layer deposited to an optically opaque thickness. The fraction of the surface covered by a metallic layer formed as a mesh and having an optically opaque thickness may be sufficiently low to permit transparency of the metallic layer. A transparent mesh may be formed from a transparent or opaque metallic layer covering about 20% or less of the surface. A transparent mesh may take the form of a regular array. A transparent mesh need not have a regular or patterned structure, and may have a randomised or other non-repeating structure.

According to a second aspect of the invention, there is provided a metallic layer including one or more of copper, silver and gold selectively deposited on a surface. The metallic layer is formed by depositing a fluorinated layer on the surface, the fluorinated layer having a thickness sufficient to substantially prevent deposition of the copper, silver and/or gold between the fluorinated layer and the surface during a subsequent evaporation step using a given deposition rate, and forming the metallic layer by evaporating, at the given deposition rate, the copper, silver and/or gold over the surface and the fluorinated layer, wherein the copper, silver and/or gold preferentially adhere to the portions of the surface not covered by the fluorinated layer.

Forming the metallic layer may include depositing the fluorinated layer as a negative image of a pattern, and the metallic layer may be deposited according to the pattern. The pattern may take the form of a regular array of features. The pattern may include a circuit pattern or a part of a circuit diagram.

Forming the metallic layer may include depositing the fluorinated layer by applying droplets of a fluorinated compound to the surface until a fraction of the surface covered by the fluorinated layer is equal or approximately equal to a predetermined fraction. The fraction of the surface covered by the metallic layer may be approximately the complement of the predetermined fraction. The droplets of the fluorinated compound may have a known size distribution. The droplets of the fluorinated compound may be applied to the surface for a pre-calibrated duration. The predetermined fraction may be determined based on a desired reflectance and/or transmittance of the metallic layer.

Forming the metallic layer may also include a washing process to remove the fluorinated layer without removing the metallic layer.

The metallic layer may have been formed according to the method of selectively depositing a metallic layer comprising one or more of copper, silver and gold according to the first aspect of the invention. The metallic layer may include features corresponding to any features of the first aspect

According to a third aspect of the invention, there is provided a metallic layer including one or more of copper, silver and gold deposited on a surface, wherein a fluorinated layer covers those parts of the surface from which the metallic layer is absent.

The surface may be coated with an adhesion layer, and the metallic layer may be deposited over the adhesion layer.

The fluorinated layer may include a fluorinated polymer. The fluorinated layer may include a fluorinated non-polymeric molecule. The fluorinated layer may consist of or include any highly fluorinated organic molecule or polymer. Highly fluorinated may mean that 50% or more of carbon-hydrogen bonds in an organic molecule or polymer are substituted by carbon-fluorine bonds. The fluorinated layer may consist of or include any highly fluorinated hydrocarbon. The fluorinated layer may consist of or include any perfluorocarbon (i.e. a molecule or polymer containing just carbon and fluorine). The fluorinated layer may consist of or include any perfluorinated compounds. The fluorinated layer may consist of or include a mixture of highly fluorinated molecules or polymers. The fluorinated layer may consist of or include trichloro(1H,1H,2H,2H-perfluorooctyl)silane (FTS) or 1H,1H,2H,2H-perfluorododecyltrichlorosilane or 1H,1H,2H,2H-perfluorodecyltriethoxysilane or 1H,1H,2H,2H-Perfluorooctyltriethoxysilane. The fluorinated layer may consist of or include poly(vinylidene fluoride-co-hexafluoropropylene) (PVDF-HFP, (—CH₂CF₂-)ₓ[—CF₂CF(CF₃)—]_{y}), poly(vinylidene fluoride), poly(tetrafluoroethylene), poly(chlorotrifluoroethylene) or perfluoropolymer, P(TTD-TFE), poly(tetrafluoroethylene-co-2,2,4-trifluoro-5-trifluoromethoxy-1,3-dioxole).

The metallic layer may have an optically transparent thickness.

The metallic layer may have an optically opaque thickness.

The metallic layer may include a transparent mesh.

The metallic layer may have been formed according to the method of selectively depositing a metallic layer comprising one or more of copper, silver and gold according to the first aspect of the invention. The metallic layer may include features corresponding to any features of the first aspect.

An electronic device may include the metallic layer according to the second or third aspects.

A photovoltaic device or organic photovoltaic device may include the metallic layer according to the second or third aspects.

A touch panel or touchscreen panel may include the metallic layer according to the second or third aspects. A light emitting device or an organic light emitting device may include the metallic layer according to the second or third aspects. A sensor may include the metallic layer according to the second or third aspects.

### BRIEF DESCRIPTION OF THE DRAWINGS

Certain embodiments of the present invention will now be described, by way of example, with reference to the accompanying drawings in which:

FIG. 1 is a process flow diagram of a method of selective metal deposition;

FIGS. 2A to 2G illustrate steps of a method of selective metal deposition;

FIGS. 3A to 3K show experimental data characterising patterned silver metallic layers, including scanning electron microscopy (SEM) images (3A to 3D and 3J), energy dispersive x-ray spectroscopy (EDXS) spectra (3E), high-resolution transmission electron microscopy (HRTEM) images (3F, 3G), atomic force microscopy (AFM) scans and associated AFM line profiles (3H, 3I), and a photograph (3K);

FIG. 4 shows cross-sectional HRTEM images of a patterned silver metallic layer;

FIG. 5 shows cross-sectional HRTEM images of a patterned silver metallic layer and corresponding EDXS maps;

FIG. 6 shows cross-sectional HRTEM images of apertures in a silver metallic layer;

FIG. 7 shows cross-sectional HRTEM images and corresponding EDXS maps for apertures in a silver metallic layer;

FIG. 8 shows experimental data characterising patterned silver metallic layers, including SEM images (8A to 8C), EDXS spectra (8D), AFM scans (8E, 8F), and an AFM line profile (8G corresponding to a line shown in 8F);

FIG. 9 illustrates nucleation of metallic particles during formation of a metallic film;

FIGS. 10 and 11 illustrate isolated metallic particles, and other types of defect;

FIGS. 12A and 12B show photographs of a pair of comparative samples, and schematic cross-sections corresponding to the comparative samples;

FIG. 13 shows EDXS spectra corresponding to silver metallic layers evaporated onto a number of substrates;

FIGS. 14A to 14E shows photographs of glass samples coated with a variety of different layers, or no coating, and also evaporation coated using silver;

FIG. 15 shows optical transmittance data corresponding to the samples shown in FIGS. 14A to 14E;

FIG. 16 shows normalised EDXS spectra corresponding to silicon substrates analogous to the samples shown in FIGS. 14A to 14E;

FIG. 17 shows experimental data characterising silver metallic layers deposited at a relatively high deposition rate, including SEM images (17A, 17B) and EDXS spectra (17C);

FIG. 18 shows experimental data characterising copper metallic layers, including SEM images (18A to 18D), an EDXS spectrum (18E), and a photograph (18F);

FIG. 19 shows experimental data characterising copper metallic layers, including an SEM image (19A), an EDXS spectrum (19B), an AFM scan (19C), and an AFM line profile (19D);

FIGS. 20A and 20D show AFM scans of silver metallic layers before and after a washing process;

FIGS. 20B and 20E show the AFM scans of FIGS. 20A and 20D from above;

FIGS. 20C and 20F show the AFM line profiles corresponding to lines shown in FIGS. 20B and 20E respectively;

FIG. 21 shows experimental data characterising gold metallic layers, including SEM images (21A, 21B), an EDXS spectrum (21C), AFM scans (21D, 21E) and an AFM line profile (21F corresponding to a line shown in 21E); and

FIGS. 22A to 22G illustrate steps of a second method of selective metal deposition.

### DETAILED DESCRIPTION OF CERTAIN EMBODIMENTS

In the following, like parts are denoted by like reference numbers.

The present specification describes simple methods for selective deposition of thin films of copper, silver and/or gold with a potentially high density of features. Selective deposition according to the present specification may include deposition of patterned metallic films of copper, silver and/or gold. The methods according to the present specification may be more easily scaled to large areas than existing methods of patterning thin metallic films. The selective deposition methods according to the present specification may enable improvements in fundamental research, and may also open the door to new low cost applications.

As mentioned hereinbefore, there has previously been a great deal of effort directed at maximising the condensation coefficient, C, for deposition of metallic films. By contrast, the present specification is concerned with how the condensation coefficient C can be minimised, or how substrates or surfaces with low condensation coefficients C might be exploited for selective deposition of copper, silver, gold and/or alloys thereof.

The present specification concerns methods for the selective deposition of metallic films including copper, silver and/or gold by simple thermal evaporation (or similar deposition methods). The methods of the present specification may enable fabrication of dense arrays of tiny apertures of any printable shape. The dimensions of a pattern deposited according to the methods of the present specification are limited only by the printing technique used. The inventors have found that a thin fluorinated layer, for example ≥10 nm, of highly fluorinated molecules, may be effective at blocking copper or silver deposition. Highly fluorinated in this context may refer to 50% or more of carbon-hydrogen bonds in an organic molecule or polymer being substituted by carbon-fluorine bonds. When depositing gold, the inventors have found that a thicker fluorinated layer, for example ≥20-30 nm, may be effective. In general, the thickness of the fluorinated layer used should be optimised in dependence on the metal or metals being deposited, the deposition rate, and so forth. Details of procedures for optimising the thickness of the fluorinated layer according to the methods of the present specification are set out hereinafter.

Metal deposition occurs only, or substantially only, in regions where the fluorinated layer does not cover a substrate or surface being coated. In other words, the amount of copper, silver and/or gold deposited on or over portions of the substrate or surface covered by the fluorinated layer is significantly lower than the amount of copper, silver and/or gold deposited on or over portions of the substrate or surface not covered (i.e. left exposed) by the fluorinated layer.

In practical circumstances, there are always small amounts of copper, silver and/or gold deposited on or over portions of the substrate or surface covered by the fluorinated layer, or between the fluorinated layer and the substrate. The amount typically increases with the metal thickness and also with the evaporation deposition rate. The latter is believed to be because the incident metal atoms have more thermal energy and so diffuse further into the fluorinated layer, which is typically of relatively low density. The former is because in practice there are always defects in the fluorinated layer, and also in practice the condensation coefficient C value is not actually zero, but just very small, for some or all of the suitable fluorinated layers. The amount of copper, silver and/or gold deposited on or over portions of the substrate or surface covered by the fluorinated layer, or between the fluorinated layer and the substrate, may be minimised by optimising the thickness of the fluorinated layer, and is preferably negligible. The amount of copper, silver and/or gold deposited on or over portions of the substrate or surface covered by the fluorinated layer, or between the fluorinated layer and the substrate, may be considered negligible if the amount of copper, silver and/or gold deposited in these areas remains below the percolation threshold. The amount of copper, silver and/or gold deposited on or over portions of the substrate or surface covered by the fluorinated layer, or between the fluorinated layer and the substrate, may be considered negligible if the amount of copper, silver and/or gold deposited in these areas remains sufficiently thin and/or dispersed as to remain optically transparent.

The low thickness of the fluorinated layer means that it may be left in-situ or simply rinsed away following deposition of a patterned metallic layer. Whether or not the fluorinated layer is removed may typically depend on the application. Examples shall be presented hereinafter which demonstrate using the present methods with micro-contact printing to fabricate optically thin and opaque film of metals which include millions of apertures cm⁻². An advantage of the methods of the present specification is the removal of the need for selective removal of metal. This reduces wastage of materials, such as expensive metals, and also minimises the environmental impact of disposing of chemical waste from etching. Although a very small amount of metal deposited onto the fluorinated layer could be removed in examples for which the fluorinated layer is removed by rinsing/washing, this is coincidental and not equivalent to etching. The relative simplicity of the methods of the present specification is expected to enabling new applications in diverse technological fields such as, for example, photovoltaics, sensors, electronics and so forth.

Another useful effect of the methods according to the present specification is that, if the fluorinated layer is not rinsed off, then the surface of the metallic layer is left clean and is not contaminated by solvent residue or solvent. This may be especially advantageous for applications in organic electronics, because the work functions of metals may be strongly affected by surface adsorbants.

The inventors of the present specification have found that thin film fluorinated layers, for example made from fluorinated molecules and/or fluorinated polymers, may be effective at blocking copper, silver and/or gold deposition (≥˜10 nm for copper or silver, ≥˜20-30 nm for gold), across a thickness range of metallic layers from optically thin (≤15 nm) to optically thick (≥85 nm), and within the range between. The metal deposition occurs preferentially in regions where the fluorinated layer does not cover the substrate.

### Method of Depositing Patterned Metallic Layers

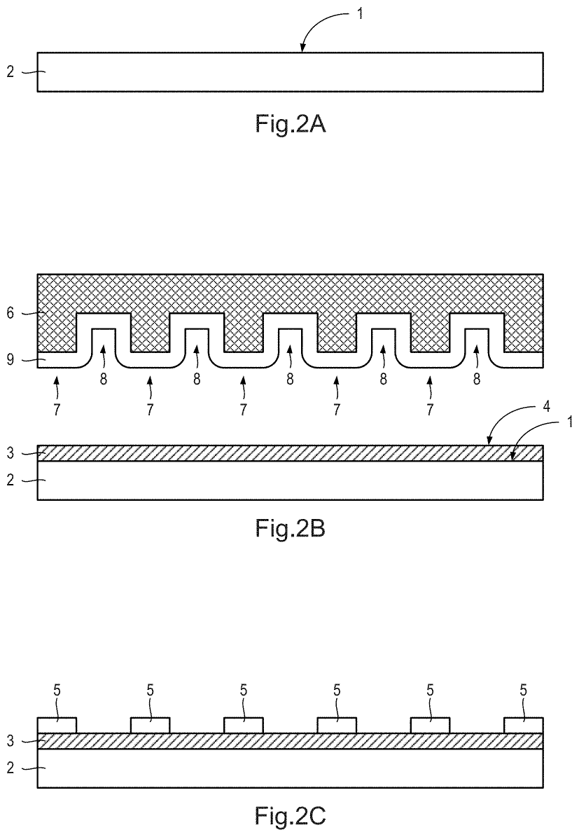

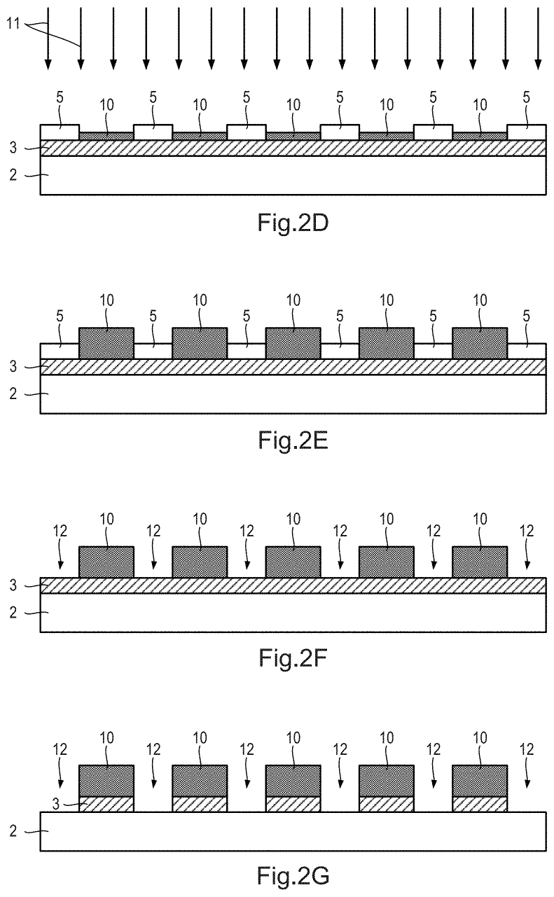

The present specification is concerned with a method of selectively depositing a metallic layer 10 (FIG. 2E). The metallic layer 10 (FIG. 2E) may include one or more of copper, silver and gold. The method includes depositing a fluorinated layer 5 (FIG. 2C) on a surface 1, 4 (FIG. 2B). The fluorinated layer 5 (FIG. 2C) has a thickness sufficient to prevent deposition of the copper, silver and/or gold between the fluorinated layer 5 (FIG. 2C) and the surface 1, 4 (FIG. 2B) during a subsequent evaporation step using a given deposition rate. For example, for deposition of copper or silver, the fluorinated layer 5 (FIG. 2C) should have a thickness of greater than or equal to about 10 nm, whereas for deposition of gold the fluorinated layer 5 (FIG. 2C) should have a greater thickness, for example, greater than or equal to about 20-30 nm. The method also includes forming the metallic layer 10 (FIG. 2E) by evaporating, at the given deposition rate, the copper, silver and/or gold over the surface 1, 4 (FIG. 2B) and the fluorinated layer 5 (FIG. 2C). The copper, silver and/or gold preferentially adhere to the portions of the surface not covered by the fluorinated layer (FIG. 2C).

As explained in further detail hereinafter, the metallic layer 10 (FIG. 2E) may be patterned or unpatterned, in dependence upon whether the fluorinated layer 5 (FIG. 2C) is patterned or unpatterned.

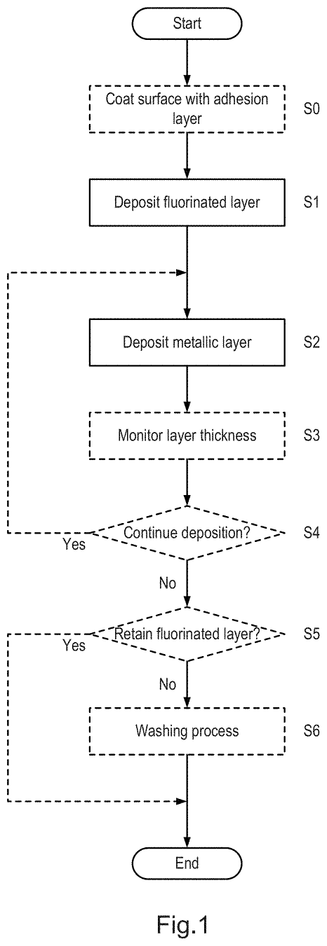

Referring to FIG. 1 and FIGS. 2A to 2G, further details of the method will be explained.

The method is for application to a surface 1. The surface 1 may be a surface of a substrate 2. The substrate 2 may include or be formed of glass, so that the surface 1 is a glass surface. The substrate 2 may include or be formed of a polymer material, so that the surface 1 is a polymeric surface. In some examples, the substrate 2 may be a semiconductor material, such as silicon. The substrate 2 may be a laminate or layered structure which includes multiple layers of materials. The substrate 2 may be transparent or opaque. The substrate may include or be formed of an organic semiconductor, an inorganic semiconductor, or an electrically insulating material.

In general, the methods of the present specification may be applicable to any surface 1 to which copper, silver and/or gold will adhere, or which may be treated or coated such that copper, silver and/or gold will adhere to the treated surface or coating.

Optionally, the surface 1 may be coated with an adhesion layer 3 (step S0). The adhesion layer 3 may be applied using any suitable method such as, for example, evaporation, spin coating, dip-coating, doctor-blading, and so forth. In some examples, the substrate 2 may be pre-coated with an adhesion layer 3.

An adhesion layer 3 may be useful to improve metal adhesion over the surface 1. For example, an adhesion layer 3 may be a thin film (for example between a molecular monolayer and several nm thickness) of a material which has an increased condensation coefficient C compared to the bare surface 1. Herein, the term condensation coefficient C refers to the proportion of evaporated metal that remains on a surface 1, 4. For example, a condensation coefficient of C=0.5 means that 50% of metal atoms incident on a surface adhere to said surface, whilst the remaining 50% do not. In this way, depending on the properties of the surface 1, the adhesion layer 3 may present an alternative surface 4 to which metal atoms may more readily adhere. Additionally or alternatively, the adhesion layer 3 may serve to modify the wetting and/or adherence properties of the fluorinated layer 5. For example, the adhesion layer 3 may improve adherence of the fluorinated layer 5, and/or the resolution (minimum feature size) of a patterned fluorinated layer 5. In another example, the adhesion layer 3 may be a material which has a high condensation coefficient C for copper, silver and/or gold, but upon which the fluorinated layer 5 will not wet. Such an adhesion layer 3 could be printed into a pattern to help define the areas to be covered/not covered by the fluorinated layer 5.

Ideally, the surface 1, or the alternative surface 4, will be characterised by a condensation coefficient C of close to unity. This may help to ensure compact thin film growth of the metallic layer 10.

For example, when the substrate 2 is made of glass, it may be advantageous to coat the substrate 2 with an adhesion layer 3 formed of an oxide, for example, molybdenum oxide or titanium dioxide. In another example, when the substrate is made of a polymer material, an adhesion layer 3 may be formed of an oxide, for example, molybdenum oxide or titanium dioxide, or the adhesion layer 3 may be formed of another polymer. For example, polyethylenimine, polyallylamine or hybrids thereof may provide suitable adhesion layers 3 for a range of polymeric substrates 2. Other potentially suitable materials for an adhesion layer 3 include organic materials such as 3-mercaptopropyltrimethoxysilane or 3-aminopropyltrimethoxysilane. Further suitable materials for an adhesion layer 3 include metals such as, for example, nickel or chromium or germanium or gold. In general, the adhesion layer 3 may include or be formed from any material, compound, alloy or mixture which may provide an alternative surface 4 having a relatively larger condensation coefficient C for the copper, silver and/or gold than the surface 1.

In other examples, the surface 1 may be an exposed layer of an electronic device (not shown) or a part of an electronic device. An electronic device may take the form of, for example, an organic or inorganic photovoltaic device, an organic or inorganic light emitting diode, a touch panel, a touchscreen, a sensor, and so forth. When the surface 1 is a surface of an electronic device, an adhesion layer 3 may be deposited in order to provide a greater condensation coefficient C. Additionally or alternatively, the adhesion layer 3 may also serve to protect underlying layers of an electronic device from diffusion/implantation of metal ions and/or a solvent used for depositing a fluorinated layer 5.

A fluorinated layer 5 is deposited onto or over the surface 1 (step S1). When an adhesion layer 3 is used, the fluorinated layer 5 is deposited over the surface 1 and onto the alternative surface 4. The thickness of the fluorinated layer 5 should be sufficient to prevent deposition of the copper, silver and/or gold between the fluorinated layer 5 and the surface 1, 4 during a subsequent evaporation step (step S2) using a given deposition rate. For example, for deposition of copper or silver, the fluorinated layer 5 should have a thickness of greater than or equal to about 10 nm, whereas for deposition of gold the fluorinated layer 5 (FIG. 2C) should have a thickness of greater than or equal to about 20-30 nm. Without wishing to be bound by theory, it is thought that the thickness of the fluorinated layer 5 needs to be sufficient to prevent metal atoms from implanting and/or diffusing through the fluorinated layer 5 and nucleating metal regions beneath the fluorinated layer 5.

A sufficient (i.e. minimum) thickness of the fluorinated layer 5 depends on the particular conditions of deposition, including the metal or combination of metals which are being deposited, the deposition rate for the metal or metals, the particular materials used for the fluorinated layer 5, the substrate 2, the adhesion layer 3 when present, and so forth. Methods for determining a sufficient thickness of the fluorinated layer 5 are explained hereinafter.

The fluorinated layer 5 may include, or substantially consist of, one or more fluorinated polymers. The fluorinated layer 5 may include, or substantially consist of, one or more fluorinated non-polymeric molecules. The fluorinated layer 5 may take the form of a mixture or blend of one or more fluorinated polymers and one or more fluorinated non-polymeric molecules. For example, the fluorinated layer 5 may include, or substantially consist of, trichloro(1H,1H,2H,2H-perfluorooctyl)silane (FTS) or 1H,1H,2H,2H-perfluorododecyltrichlorosilane or 1H,1H,2H,2H-perfluorodecyltriethoxysilane or 1H,1H,2H,2H-perfluorooctyltriethoxysilane. Additionally or alternatively, the fluorinated layer may consist of or include poly(vinylidene fluoride-co-hexafluoropropylene) (PVDF-HFP, (—CH2CF2-)x[—CF2CF(CF3)-]y), poly(vinylidene fluoride), poly(tetrafluoroethylene), poly(chlorotrifluoroethylene) or Hyflon®.

In general, the fluorinated layer may consist of or include any highly fluorinated hydrocarbon, such as, for example highly fluorinated molecules, polymers or co-polymers, including mixtures or blends of two or more highly fluorinated molecules, polymers or co-polymers. In general, the fluorinated layer may consist of or include any highly fluorinated organic molecule or polymer, highly fluorinated hydrocarbon, perfluorocarbon (i.e. a molecule or polymer containing just carbon and fluorine), perfluorinated compounds, and so forth.

When a patterned metallic layer 10 is desired, the fluorinated layer 5 may be deposited as a negative image of the desired pattern of a metallic layer 10. In other words, the fluorinated layer 5 overlies every part of the surface 1 which should not be covered by the patterned metallic layer 10. For exampling, the fluorinated layer 5 may be formed by printing, which enables forming a detailed negative image of the desired pattern. The pattern used for a metallic layer 10 may take any form, limited only by the resolution of forming the fluorinated layer 5, for example the resolution of printing the fluorinated layer 5. In some examples, a patterned metallic layer 10 may take the form of a regular array of features. In other examples, a patterned metallic layer 10 may take the form of a circuit pattern or a part of a circuit pattern.

For example, referring in particular to FIGS. 2B and 2C, an example of using micro-contact printing is illustrated.

Micro-contact printing uses a stamp 6. The stamp 6 includes a number of raised regions 7 and recessed regions 8. The raised regions 7 define the pattern to be printed for the fluorinated layer 5. The stamp 6 is coated with a layer of ink 9. The ink 9 is any ink which, upon drying and/or curing, will form the fluorinated layer 5. Curing may include, for example, thermal or infrared baking and/or treatment using ultraviolet (UV) light. The stamp 6 coated with ink 9 is pressed against the surface 1, or when an adhesion layer 3 is used the alternative surface 4, and the ink 9 coating the raised regions 7 is transferred to the surface 1, 4. The ink 9 coating the recessed regions 8 does not contact the surface 1, 4 and is not transferred. The stamp 6 is often formed of an elastomeric material such as, for example, polydimethylsiloxane (PDMS). However, in general the stamp 6 may be made of any material suitable for evenly wetting the ink layer 9 and permitting good transference to the surface 1, 4.

Printing of the fluorinated layer 5 does not need to be performed using micro-contact printing, and may alternatively use any suitable printing technique such as, for example, ink-jet printing, gravure printing, flexographic printing, and so forth. In general, the selection of printing method may depend on a variety of factors, including but not limited to, the desired feature size of the fluorinated layer 5, the total area of surface 1, 4 to be covered, the cost, and so forth.

In other examples, the fluorinated layer 5 does not need to be printed, and may instead be formed by any other suitable method such as, for example, spray-deposition or dip-coating followed by lithographic techniques to selectively remove portions of the fluorinated layer 5 to form the negative image of the desired pattern of metallic layer 10.

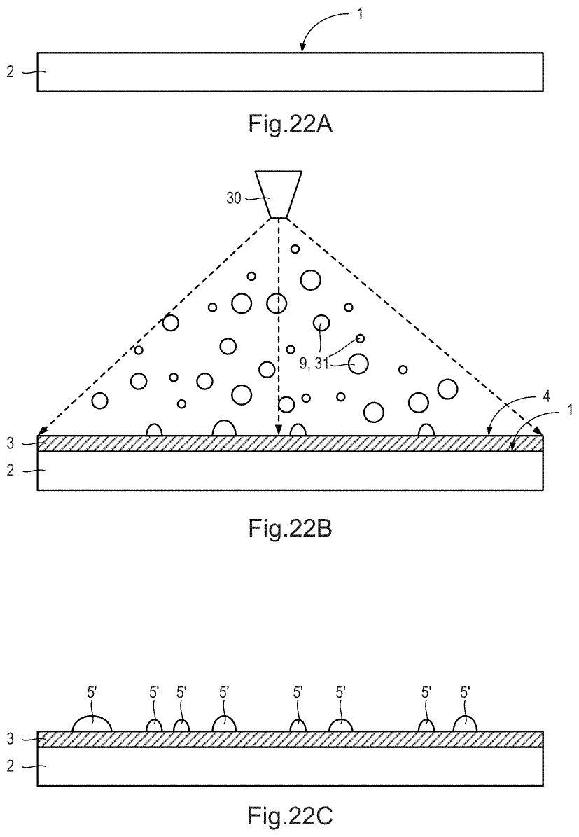

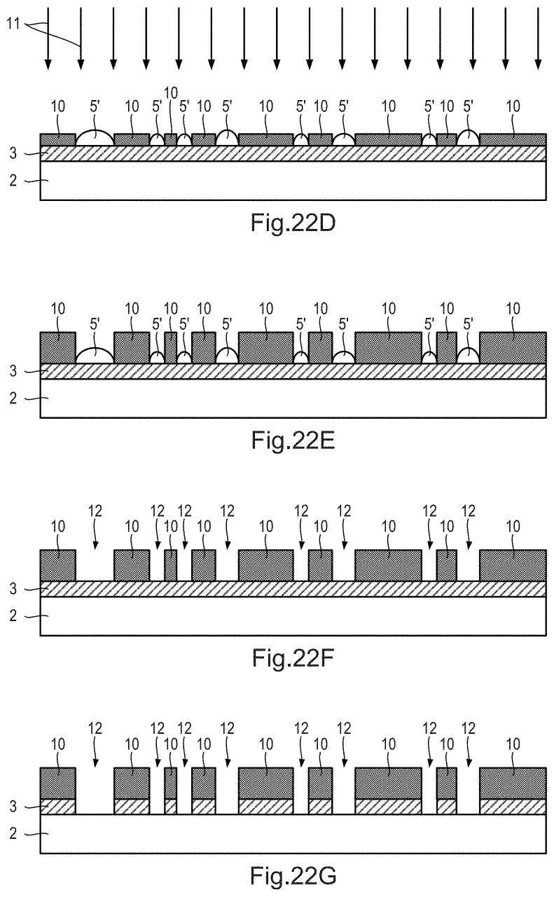

For example, the fluorinated layer may be deposited by applying droplets of ink 9 to the surface until a fraction of the surface covered by the fluorinated layer 5 is equal or approximately equal to a predetermined fraction (see FIGS. 22A to 22G and accompanying description hereinafter).

The metallic layer 10 is deposited by evaporating metal atoms 11 over the surface 1, 4 and fluorinated layer 5 (step S2). The metal atoms 11 include one or more types selected from the group of copper, silver and gold. The metal atoms 11 preferentially adhere to the portions of the surface 1, 4 not covered by the fluorinated layer 5. Evaporation may be conducted in vacuum, and may include thermal, electron beam, resistive or flash evaporation.

In this way, selective deposition of copper, silver, gold or alloys/mixtures thereof is achieved. When the fluorinated layer 5 is patterned, for example by printing the fluorinated layer 5, the desired pattern of metallic layer 10 may be formed as the negative of the fluorinated layer 5. In other words, the metallic layer 10 is formed over the parts of the surface 1, 4 which are not covered by the fluorinated layer 5. In other examples, the fluorinated layer 5 may be unpatterned, for example in the form of randomly sprayed droplets. However, the metallic layer 10 may still be formed over the parts of the surface 1, 4 which are not covered by an unpatterned fluorinated layer 5.

The portions of the surface 1, 4 covered by the fluorinated layer 5 may be free, or substantially free, of copper, silver and/or gold. Although in practice some metal atoms 11 will be deposited on or over the areas of the surface 1, 4 covered by the fluorinated layer 5, or between the fluorinated layer 5 and the surface 1, 4, the rate of deposition of copper, silver and/or gold on the portions of the surface 1, 4 not covered (i.e. left exposed) by the fluorinated layer 5 should preferably be at least five times, or at least ten times higher than the rate of deposition of copper, silver and/or gold over or on the portions of the surface 1, 4 covered by the fluorinated layer 5, or between the fluorinated layer 5 and the surface 1, 4.

In practice, selective deposition is achieved if the properties of the metallic layer 10 are sufficiently different between the portions of the surface 1, 4 covered by the fluorinated layer 5 and the portions of the surface 1, 4 not covered by the fluorinated layer 5. When electrical conductivity of the metallic layer 10 is desired, selective deposition may be achieved when the portions of the surface 1, 4 covered by the fluorinated layer 5 have sufficiently low conductance. In another example where it is desired to control reflectance of a surface 1, 4 using the metallic layer 10, selective deposition may be achieved when the portions of the surface 1, 4 covered by the fluorinated layer 5 have sufficiently low reflectance.

The metallic layer 10 may consist of substantially pure copper, gold, or silver. Substantially pure may refer to ≥95%, ≥99% or ≥99.9% of the metallic layer by weight being copper, gold, or silver. Alternatively, the metallic layer 10 may be an alloy or mixture of copper, gold, and/or silver, in any pairing, or including all three metals.

Optionally, the metallic layer 10 may take the form of a multi-layer structure which includes two or more distinct layers, each layer formed of copper, silver or gold. In one example, for display applications in which the metallic layer 10 is sufficiently thin to be transparent, it may be useful to combine silver with copper because thin films of these metals have complimentary absorption in the visible spectrum. In another example, for a metallic layer 10 forming a grid electrode in which the grid lines are optically opaque, relatively cheaper copper may be deposited to form the bulk of the thickness of the metallic layer 10, followed by a thin film of silver to serve as a passivation layer protecting against oxidation. The same fluorinated layer 5 may permit selective deposition of all layers of a multi-layer structure, provided that the thickness of the fluorinated layer 5 is sufficiently thick for each deposition process.

The metallic layer 10 may be deposited to an optically transparent thickness. Transparent may refer to transmitting ≥50% of incident light, ≥75% of incident light ≥900% of incident light, or ≥95% of incident light. An optically transparent thickness may mean that the metallic layer 10 does not exceed an optical skin depth. A metallic layer 10 may be optically transparent when it has a thickness of less than or equal to about 15 nm. A metallic layer may be optically transparent or part-transparent when it has a thickness of between about 15 nm and about 85 nm. A metallic layer 10 may be optically transparent when it transmits more than 50%, more than 75%, more than 80%, more than 90% or more than 95% of incident light. For applications in organic or inorganic photovoltaics, the average far-field transparency of a metallic layer 10 may preferably be 800% (across the range from 400 nm to 900 nm). For applications in a display such as a liquid crystal display (LCD) or an organic light emitting diode display (OLED), it is preferable for the transmittance of a metallic layer 10 to be substantially constant across the visible spectrum and greater than about 80%. For emissive glass applications, such as controlling or modifying the thermal characteristics of a building, the average optical transparency is preferably as high as possible, for example at least 80%.

Alternatively, the metallic layer 10 may be deposited to an optically opaque thickness. An optically opaque thickness may mean that the metallic layer 10 equals or exceeds an optical skin depth. A metallic layer 10 may be optically opaque when it has a thickness of greater than or equal to about 85 nm. A metallic layer 10 may be optically opaque when it transmits less than 50%, less than 25%, less than 10% or less than 5% of incident light

In a further example, the metallic layer 10 may be deposited as a transparent mesh. The metallic regions forming a transparent mesh may by optically transparent or may be optically opaque. However, even when the metallic regions forming a transparent mesh are thick enough to be optically opaque, the mesh overall may be transparent if the spacing of metallic regions is sufficiently large and the area fraction of metallic regions is sufficiently low. For example, a transparent mesh may be formed from a transparent or opaque metallic layer 10 covering 20% or less of the surface 1, 4. A transparent mesh may be provided by a metallic layer 10 formed into a regular array. However, a metallic layer 10 forming a transparent mesh need not have a regular or patterned structure, and may have a randomised or other non-repeating structure (see FIGS. 22A to 22G and the accompanying description hereinafter).

The deposition of the metallic layer 10 may be carried out for a pre-set duration, in order to provide a desired thickness. The pre-set duration may be determined from initial calibration experiments, in order to determine the duration needed to obtain a desired thickness of the metallic layer 10.

Alternatively, in some examples in-situ measurements of the metallic layer thickness 10 may be measured or tested (step S3). In-situ measurements of the metallic layer thickness may be performed using any suitable technique. Commonly, thicknesses of evaporated layers may be monitored using a quartz-crystal micro-balance located in the deposition chamber and proximate to the substrate 2 onto which the metallic layer 10 is being deposited. As a layer of metal condenses on the oscillating quartz crystal, its frequency of oscillation changes in a way that can be correlated with the layer thickness. If properly calibrated a quartz-crystal micro-balance can be extremely accurate. In other examples, the absolute thickness of the metallic layer 10 may be less important that the properties of the metallic layer 10, such as optical or electrical properties. Optical properties of the metallic layer 10 may be monitored using, for example the attenuation of a laser beam shone through a transparent surface 1, or the intensity of reflection of a laser beam from a metallic layer 10 being deposited on an opaque surface 1. Electrical properties may be monitored using, for example, conductive probes to measure a sheet resistance or other electrical property of interest. In-situ measurements of the metallic layer 10 thickness are preferably performed concurrently with deposition (step S2). Alternatively, the deposition (step S2) may be paused periodically to permit measurements of the metallic layer 10 thickness. Whilst the metallic layer 10 has not reached the desired thickness, the deposition (step S2) may be continued (step S4).

In some examples, there may be no need to remove the thin, ˜10-30 nm, fluorinated layer 5, and the method may end after depositing the metallic layer 10 (step S5; yes).

The output in this instance will be a metallic layer 10 which includes one or more of copper, silver, gold or alloys thereof selectively deposited on or over the surface 1 (or on the alternative surface 4 when an adhesion layer 3 is used). The metallic layer 10 may be patterned or unpatterned, depending on whether the fluorinated layer 5 was patterned. The parts of surface 1 (or the alternative surface 4 when an adhesion layer 3 is used) which are not covered by the metallic layer 10 (i.e. those parts of the surface 1, 4 where there is significantly less or a negligible quantity of copper, silver and/or gold) will be covered by the fluorinated layer 5. In other words, the apertures 12 between portions of the metallic layer 10 will still contain the fluorinated layer 5 (FIG. 2E).

In other examples, the fluorinated layer 5 may optionally be removed following deposition of the metallic layer 10 (step S5; no). For example, the method may optionally include a washing process to remove the fluorinated layer 5 (step S6) without removing the metallic layer 10. In one example, the washing process may include using a solvent to dissolve or detach the fluorinated layer, such as rinsing with tetrabutylammonium fluoride/tetrahydrofuran solution. The washing process may also include washing with water.

In general, the washing process (step S6) may use any solution of a chemical substance that can dissolve or detach the fluorinated layer 5 without removing the metallic layer 10. Other examples include rinsing with an acid solution such as, for example, hydrochloric acid (HCl), or a solvent such as, for example, acetone or dimethylacetamide or hydrofluoroether. Often, the washing process (step S6) may include washing with the same solvent or solvents used for the step of depositing the fluorinated layer (step S2).

Referring in particular to FIG. 2F, the result of removing the fluorinated layer 5 is a metallic layer 10 on or over a surface 1 (or on the alternative surface 4 when an adhesion layer 3 is used), with empty regions or apertures 12 separating the portions of the metallic layer 10.

In other examples, the washing process (step S6) may additionally or alternatively target an adhesion layer 3. For example, the washing process (step S6) may include washing with one or more solvents and/or solutions of chemical substances which dissolve or detach the adhesion layer 3. The portions of the adhesion layer 3 which are covered by the copper, silver and/or gold may be protected by the metallic layer 10, or at least may be not dissolved as rapidly, allowing selective removal of the fluorinated layer 5 by removing the underlying adhesion layer 3. For example, water may be used to dissolve an adhesion layer 3 formed of MoO₃.

Referring in particular to FIG. 2G, the result of removing the adhesion layer 3 where is not protected by the metallic layer 10 is a metallic layer 10 on or over a surface 1 (or on the alternative surface 4 when an adhesion layer 3 is used), with empty regions or apertures 12 down to the bare surface 1 of the substrate 2 separating the portions of the metallic layer 10.

A metallic layer 10 produced according to the methods of the present specification may be identified even after removal of the fluorinated layer 5, for example, using the distinctive microstructural artefacts in the form of isolated metallic nanoparticles 13 (FIG. 11), which in general may be found close to the boundaries of regions which were covered by the fluorinated layer 5. The formation of isolated metallic nanoparticles 13 is discussed in further detail hereinafter. Across a surface patterned with thousands, hundreds of thousands or even millions of features, it will in practice always be possible to observe a finite population of microstructural artefacts which are distinctive of the method of forming said features. Moreover, alternative patterning techniques such as photolithography, electron-beam lithography and so forth will produce different microstructural artefacts to the methods of the present specification.

Metallic layers 10 produced according to the methods of the present specification may be included in, or formed as an integral part of, an electronic device (not shown). An electronic device (not shown) including the metallic layer 10 may take the form of, for example, a photovoltaic device, a touch panel or touchscreen panel, an organic light emitting device, a sensor, and so forth.

Using the methods of the present specification, it is possible to perform selective deposition of patterned or unpatterned (ordered or not-ordered) metallic layers 10 including one or more of copper, silver and gold by simple thermal evaporation. The methods of the present specification enable the fabrication of dense arrays of apertures of any printable shape, or any other features formed by the presence or absence of shaped regions of a metallic film, with dimensions limited only by the printing technique (or other deposition technique) used to form the fluorinated layer 5.

The methods of the present specification are well suited to large volume or roll-to-roll type production processes. Enabling selective deposition for copper, silver and/or gold is particularly advantageous as these coinage metals do not necessary require the extremely low partial pressures of oxygen which must be used for depositing more reactive metals such as aluminium.

### Experimental Data

As a demonstration of the methods of the present specification, micro-contact printing (μCP) was used to print fluorinated layers 5 in the form of arrays of 2.5 micron diameter circles of the fluorinated molecule trichloro(1H,1H,2H,2H-perfluorooctyl)silane (FTS) with a density of ˜6 million apertures 12 cm⁻², onto a variety of surfaces 1, 4 of substrates 2 having relatively high condensation coefficients C. Micro-contact printing was performed using an elastomeric polydimethylsiloxane (PDMS) stamp 6 having raised regions 7 for making intimate conformal contact with the substrate 2. Micro-contact printing is a suitable technique for the selective printing of thin films on surfaces, and may be scaled to relatively large areas, as well as being easily implementable on smaller scales. Hereinafter, experiments and results shall be described in relation to applying the methods of the present specification, using both polymeric and non-polymeric molecule fluorinated compounds to form the fluorinated layer 5, and using a range of substrates 2 including glass, plastic and silicon, for deposition of copper, silver and gold.

The widely available fluorinated molecule trichloro(1H,1H,2H,2H-perfluorooctyl)silane (FTS) is one example of a material for the fluorinated layer 5 which offers an extremely low condensation coefficient, C, for both copper and silver when deposited by thermal evaporation. For the samples described hereinafter, adhesion layers 3 were used. The adhesion layers 3 tested were formed of molybdenum trioxide (denoted as MoO₃₋ₓ because evaporated molybdenum oxide is known to be partially reduced) or polyethylenimine (PEI). Both MoO₃₋ₓ and PEI can be deposited onto glass substrates 2, plastic substrates 2, or other compatible substrates.

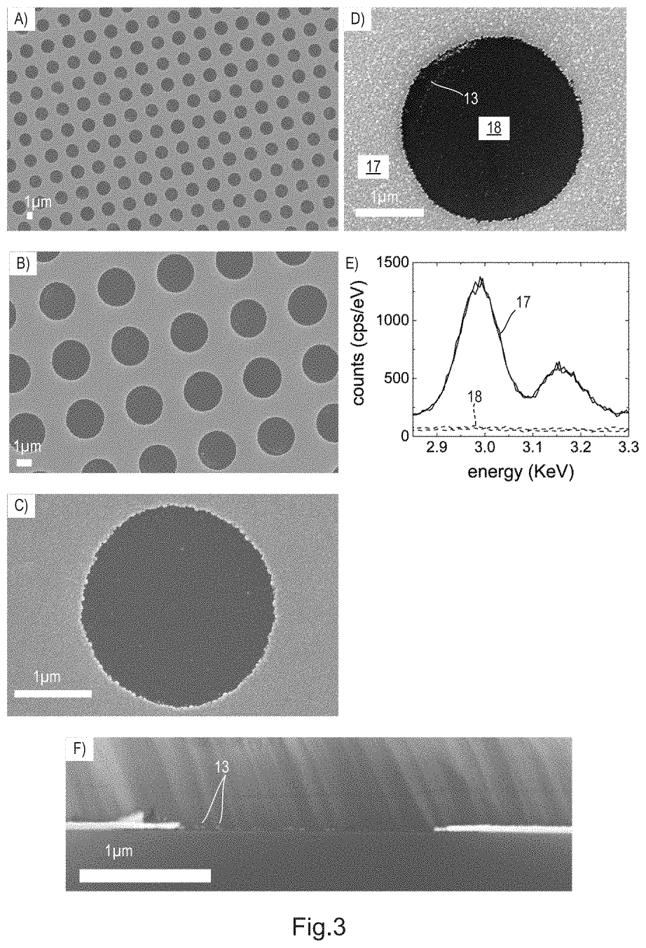

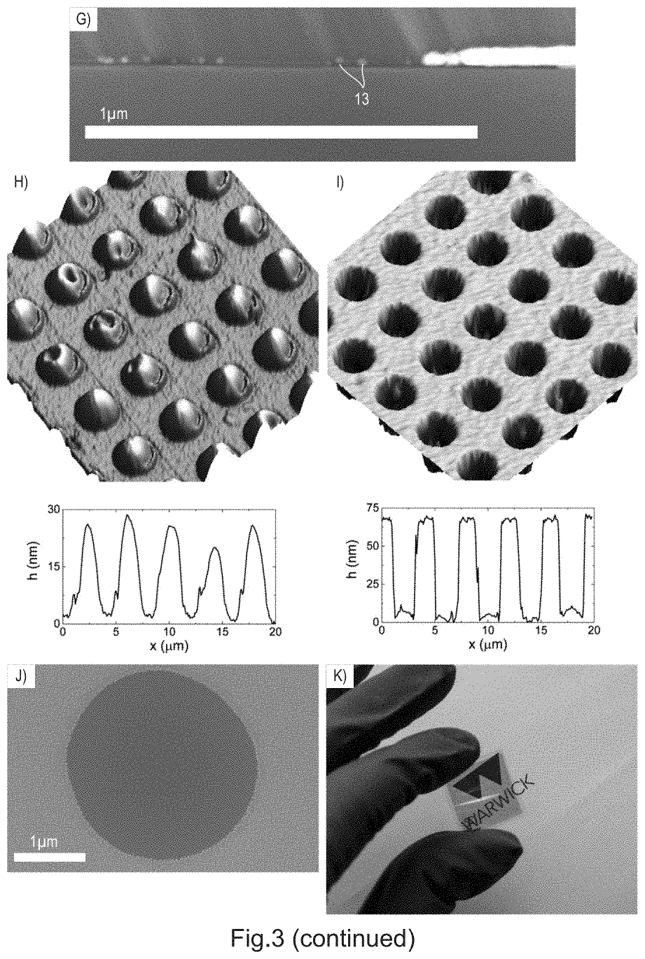

FIGS. 3 to 8 include representative scanning electron microscope (SEM) and high resolution cross-sectional transmission electron microscope (HR-TEM) images of nm, 50 nm and 85 nm thick silver metallic layers 10 thermally evaporated onto fluorinated layers 5 in the form of FTS printed films printed with 2.5 micron circular apertures 12 as described hereinbefore. In each of FIGS. 3A to 3D, 3F, 3G and 3J, the indicated scale bars correspond to 1 μm.

Referring in particular to FIGS. 3A, 3B and 3C scanning electron microscope (SEM) images are shown of a sample made by evaporating a nominally 85 nm thick silver metallic layer 10 over a fluorinated layer 5 in the form of a FTS film printed on a MoO₃₋ₓ adhesion layer 3 which was coated on a glass substrate 2.

Referring in particular to FIG. 3D, an SEM image is shown showing one aperture 12 in a 15 nm silver metallic layer 10 evaporated over a fluorinated layer 5 which was micro-contact printed using FTS onto a MoO₃₋ₓ adhesion layer 3 evaporated on a glass substrate 2.

Referring in particular to FIG. 3E, spectra 17, 18 acquired by energy dispersive X-ray spectroscopy (EDXS) are shown corresponding to either the apertures 12 or from the nm silver metallic layer 10 as shown in FIG. 3D.

Referring in particular to FIGS. 3F and 3G, high-resolution transmission electron microscopy (HR-TEM) images are shown for analogous samples deposited on a silicon substrate 2 with a 50 nm thick silver metallic layer 10.

Referring in particular to FIG. 3H, an atomic force microscopy (AFM) scan is shown of a surface (alternative surface 4) of an MoO₃₋ₓ adhesion layer 3 which was micro-contact printed with a fluorinated layer in the form of printed FTS forming circular feature 12, which in FIG. 3H correspond to mounds of printed FTS. A height profile along one row of features is shown immediately below the AFM scan.

Referring in particular to FIG. 3I, an AFM scan is shown of a 85 nm thick silver metallic layer 10 deposited over a MoO₃₋ₓ adhesion layer 3 which was patterned with a fluorinated layer 5 of printed FTS forming circular apertures 12, a height profile along one row of holes is shown immediately below the AFM scan.

Referring in particular to FIG. 3J, an SEM image is shown of a sample made by evaporating a 15 nm thick silver metallic layer 10 over a MoO₃₋ₓ adhesion layer 2 patterned with FTS forming circular apertures 12, on a polyethylene terephthalate (PET) substrate 2.

Referring in particular to FIG. 3K, a picture (photograph) is shown of a 3.2 cm² 15 nm silver metallic layer 10 evaporated onto a MoO₃₋ₓ PET flexible substrate 2 micropatterned with FTS forming circular apertures 12.

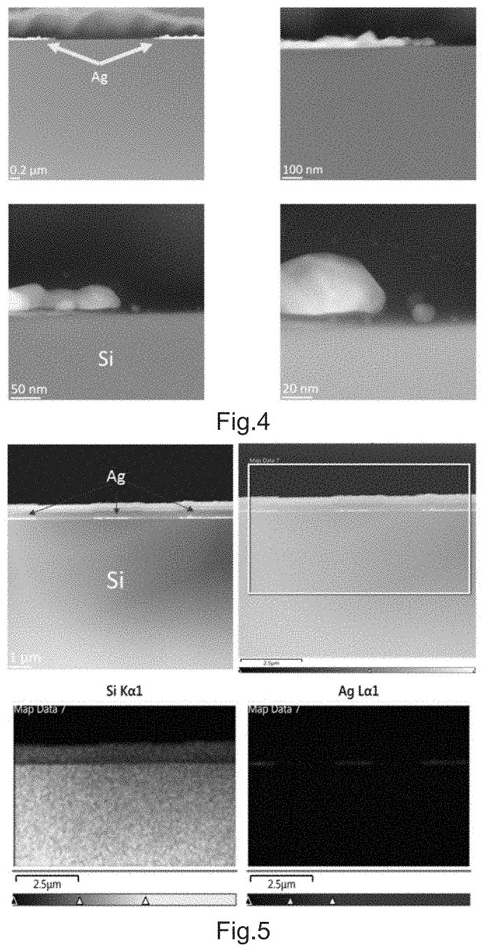

Referring in particular to FIG. 4, cross-sectional HR-TEM images are shown of an aperture 12 in a silver metallic layer 10 with nominal thickness 15 nm supported on a nm MoO₃₋ₓ adhesion layer 3, coated on a silicon substrate 2. Patterning was provided by a microcontact printed fluorinated layer 5 formed of FTS.

Referring in particular to FIG. 5, cross-sectional HR-TEM images and corresponding EDXS maps are shown for apertures 12 in a silver metallic layer 10 with nominal thickness of 15 nm supported on a 10 nm MoO₃₋ₓ adhesion layer 3 coated on a silicon substrate 2. Patterning was provided by a microcontact printed fluorinated layer 5 formed of FTS.

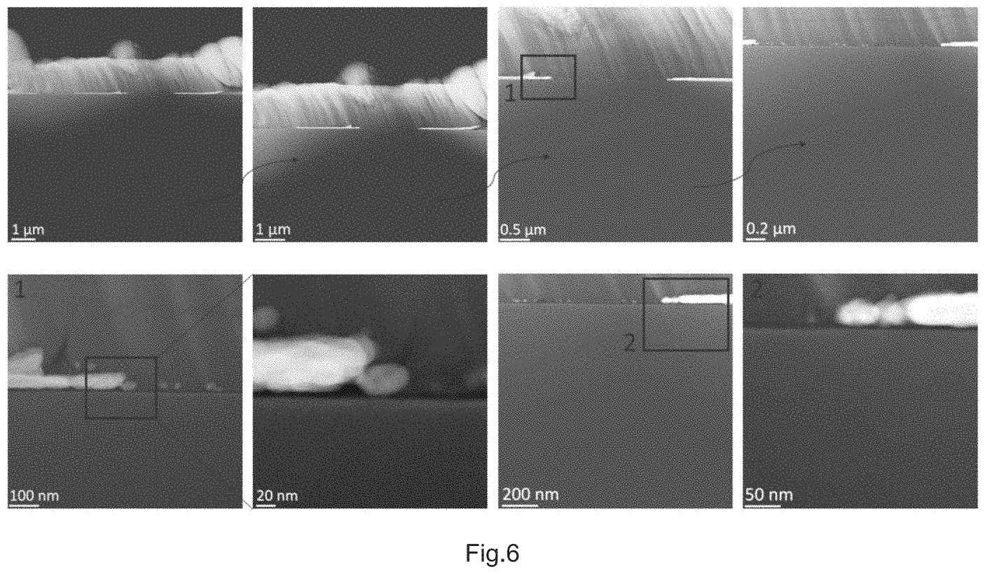

Referring in particular to FIG. 6, cross-sectional HR-TEM images are shown of apertures 12 in a silver metallic layer 10 with nominal thickness 50 nm supported on a nm MoO₃₋ₓ adhesion layer 3 coated on a silicon substrate 2. Patterning was provided by a microcontact printed fluorinated layer 5 formed of FTS.

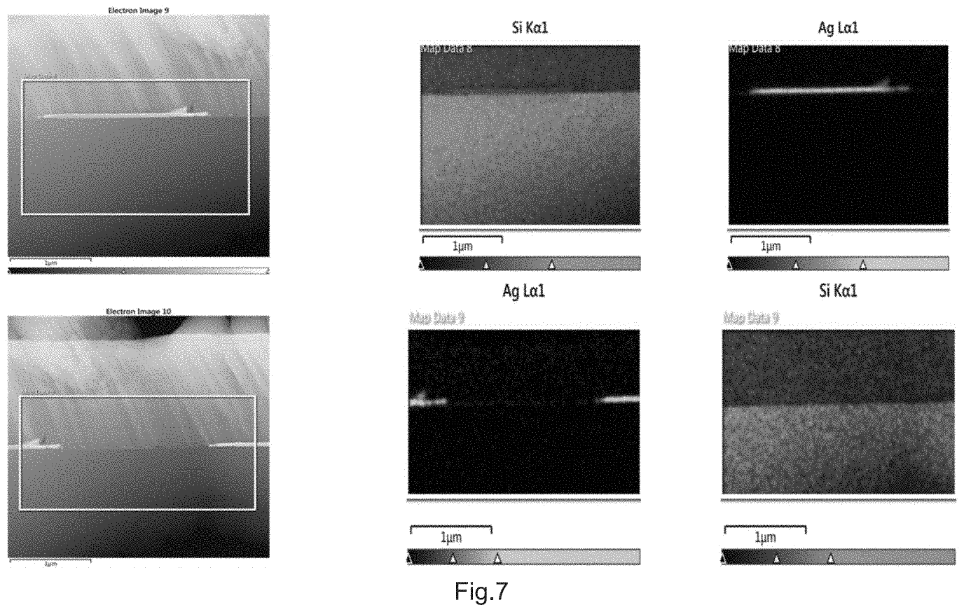

Referring in particular to FIG. 7, cross-sectional HR-TEM images and corresponding EDXS maps are shown for apertures 12 in a silver metallic layer 10 with nominal thickness 50 nm supported on a 10 nm MoO₃₋ₓ adhesion layer 3 coated on a silicon substrate 2. Patterning was provided by a microcontact printed fluorinated layer 5 formed of FTS.

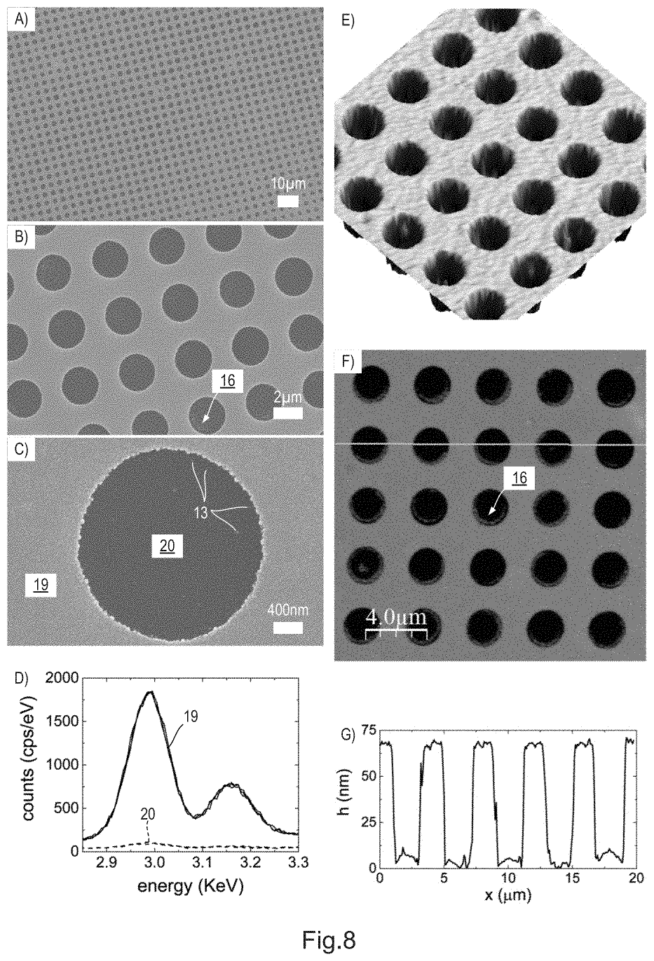

Referring in particular to FIGS. 8A, 8B and 8C, SEM images are presented of apertures (gaps 12) in a silver metallic layer 10 with nominal thickness 85 nm supported on a 10 nm MoO₃₋ₓ adhesion layer 3 coated on a glass substrate 2 printed with FTS (fluorinated layer 5) using microcontact printing.

Referring in particular to FIG. 8D EDXS spectra 19, 20 corresponding to FIG. 8C are shown which plot the silver peak acquired either from the apertures 12 or from the continuous silver metallic layer 10.

Referring in particular to FIGS. 8E and 8F, AFM scans are presented for the same sample as FIGS. 8A to 8D (though not necessarily the same region of the sample). Referring in particular to FIG. 8G, a height profile is plotted which corresponds to the line drawn in FIG. 8F.

It is evident from FIGS. 3 to 8 that the silver metallic layers 10 are selectively deposited preferentially in those areas where the substrate is not covered with the fluorinated layer 5 in the form of the FTS printed to form circular apertures 12. Spatially resolved energy dispersive X-ray spectroscopy (EDXS) spectra acquired on metallized and non-metallized areas for metallic layers 10 with a nominal thickness of nm (see FIG. 3E) and 85 nm (see FIG. 8D) confirm this observation. Of course, there was a very small amount of silver deposited in areas covered by printed FTS where the FTS was locally thin, or where there was a defect in the FTS layer, see for example the substantially smaller peaks in the spectra 18, 20 in FIGS. 3E and 8D.

Analysis of the cross-sectional HR-TEM image (see FIGS. 3F and 3G) confirms that the thickness of the metallic layers 10 is the same as that which condenses on a quartz crystal microbalance arranged next to the samples during deposition.

When the silver film thickness is increased to 85 nm (see FIGS. 3A-3C, 3I and FIG. 8), which is beyond the optical skin depth of silver, and thus optically opaque, the apertures 12 are still observed to be largely free of silver. It may be observed that such experiments demonstrate that the methods of the present specification may be applied across a broad range of metallic layer 10 thicknesses.

The SEM images and high resolution cross-sectional TEM images reveal that there are a few isolated silver nanoparticles 13 in the FTS printed regions, i.e. in the circular apertures 12 where there is substantially no metallic film 10. Several examples of such metallic nanoparticles 13 have been labelled for visualisation purposes (see for example FIGS. 3C, 3D, 3F, 3G and 8C). Such isolated metallic nanoparticles 13 may typically become larger when the thickness of the metallic layer 10 is increased, and are mainly observed around the periphery of regions of the FTS layer. In other words, the isolated metallic nanoparticles 13 are most likely to be observed where the FTS layer was becoming thinner near to the edges. Such isolated metallic nanoparticles 13 appear to be located at the interface between the MoO₃₋ₓ adhesive layer 3 and the fluorinated layer 5 in the form of printed FTS (see FIGS. 3F, 3G and 6).

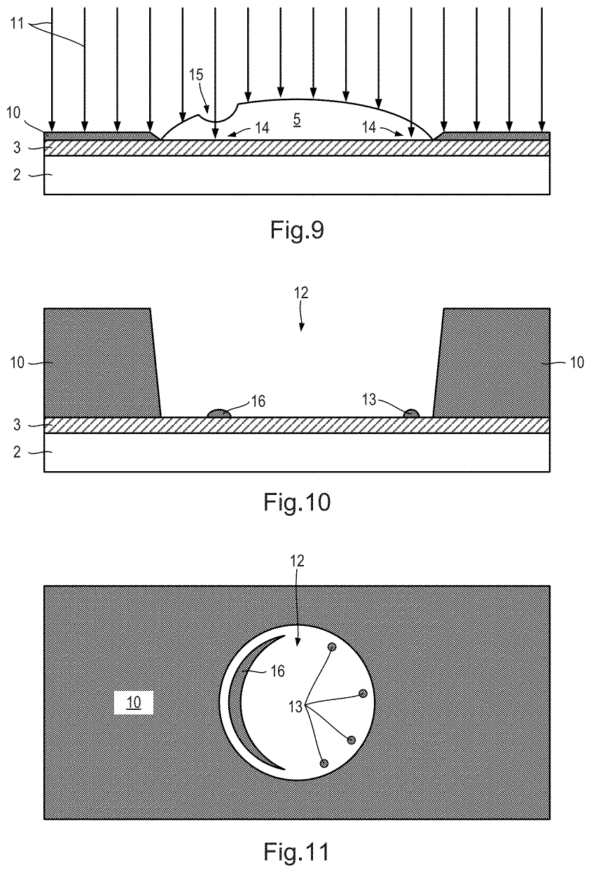

Referring also to FIGS. 9 to 11, and without wishing to be bound by theory, a potential explanation for the observation of isolated metallic nanoparticles 13 is illustrated.

It is currently thought that the observed isolated metallic nanoparticles 13 may be the result of nucleation which occurs where the metal atoms 11 have been able to penetrate and/or diffuse through the fluorinated layer 5, reaching the underlying surface 1, 4 of the substrate 2 and/or the adhesion layer 3. When the adhesion layer 3 is included, it is thought that isolated metallic nanoparticles 13 may nucleate either on the alternative surface 4 or on the interface between adhesion layer 3 and substrate 2, depending on which region is more favourable for nucleation. It is believed that close to the edges of regions of fluorinated layer 5, the fluorinated layer 5 may be thin enough to allow penetration and/or diffusion of metal atoms 11 through the fluorinated layer 5 to reach nucleation sites 14.

In practice, regardless of how the fluorinated layer 5 is printed or otherwise deposited, and regardless of the shape of the feature formed by a region of the fluorinated layer 5, there will always be some gradient in the thickness of the fluorinated layer 5 as the boundary is approached. Consequently, at or around the peripheral edges of regions of the fluorinated layer 5, it is expected that there may always be at least some isolated metallic nanoparticles 13 formed using the methods of the present specification. Because the isolated metallic nanoparticles 13 are not in general removed along with the fluorinated layer 5, analysis of distinctive microstructural features, such as the isolated metallic nanoparticles 13 concentrated around the periphery of areas covered by the fluorinated layer 5, may permit identification of metallic layers 10 formed according to the present specification, even if the fluorinated layer 5 has been removed by the washing process (step S6).

For example, it may be observed from AFM scans of fluorinated layer 5 in the form of micro-contact printed FTS layers on substrates 2, that the FTS printed regions have a rounded/mound shape with a central peak height of several tens of nanometres tapering to zero at the edges (see FIG. 3H). Inspection of the experimental data shows that where silver nanoparticles 13 are present in FTS printed regions (fluorinated layer 5), they are most prevalent at the edges of the circular apertures 12 where the printed FTS is locally thinnest (see for example FIGS. 3B, 3H, and 8). This observation is consistent with the discussion of the possible mechanism of forming isolated metallic nanoparticles 13 illustrated with reference to FIGS. 9 to 11.

Further from the boundaries, other defects or imperfections 15 in the fluorinated layer which cause local thinning may provide further nucleation sites 14. However, such other defects 15 will usually be specific to the method used for depositing the fluorinated layer 5, and unlike the metallic nanoparticles 13 do not provide generic markers associated with the methods of the present specification. Having said this, specific defects 15 associated with, for example, a particular printing process such as micro-contact printing, may be indicative of implementing the methods of the present specification using said particular printing process.

For example, one artefact of the micro-contact printing process which was observed to occur in the experimental examples is a crescent shaped trench at the outer edge of a printed circular area, where the FTS is locally thinner (visible in FIG. 3H). Such crescent shaped trenches are one example of a defect or imperfection 15 in the fluorinated layer 5 which is associated with a particular method of forming the fluorinated layer 5.

In many instances there is also a crescent shaped distribution 16 of metal which appears to correlate with the aforementioned crescent shaped local minima in the thicknesses of FTS printed areas. As discussed hereinbefore, whilst the isolated metallic nanoparticles 13 observed in the peripheral portions of areas covered by the fluorinated layer 5 are indicative of the methods of the present specification in general, the crescent shaped distributions 16 appear to be specific to micro-contact printing of circular apertures.

Together, these observations of the metallic nanoparticles 13 and other defects 15, such as the crescent shaped distributions 16, support the hypothesis that nucleation of copper, silver and/or gold may occur where the fluorinated layer 5, in this instance microcontact printed FTS, is thin enough for the silver to diffuse through to the underlying substrate 2.

It is noted that isolated metallic nanoparticles 13 are expected to be observed around the peripheral edges of any region covered by a fluorinated layer 5 for selective deposition of a metallic layer to according to the methods of the present specification.

Furthermore, such isolated metallic nanoparticles 13 would not be expected in metallic layers patterned by conventional methods such as photo-lithography and chemical etching, electron-beam lithography, and so forth. These alternative methods produce distinct and different microstructural artefacts, meaning that a trained observer will be able to identify a patterned metallic layer 10 produced according to the present specification by analysing the microstructure and observing the distinctive microstructural features discussed hereinbefore, such as the isolated metallic nanoparticles 13 concentrated in the peripheral portions of areas which are, or were, covered by the fluorinated layer 5.

Diffusion of metals into polymer substrates is a recognised phenomenon, particularly during the initial stage of polymer metallization where the system may be far away from thermodynamic equilibrium. The diffusion of metals into polymers is considered to be a consequence of the relatively weak intermolecular interactions and open surface structures of many polymer surfaces at the microscopic level.

In order to investigate the lower thickness limit of the fluorinated layer 5 which is needed to achieve selective metal deposition, in other words to block diffusion of metal atoms 11, monolayers of the monochlorosilane analogue of FTS; 1H,1H,2H,2H-perfluorooctyldimethylchlorosilane (FMS) were prepared. The monochloro analogue was used for these investigations in order to ensure that polymerisation does not occur, so the thickness is equivalent to that of one monolayer −1 nm.

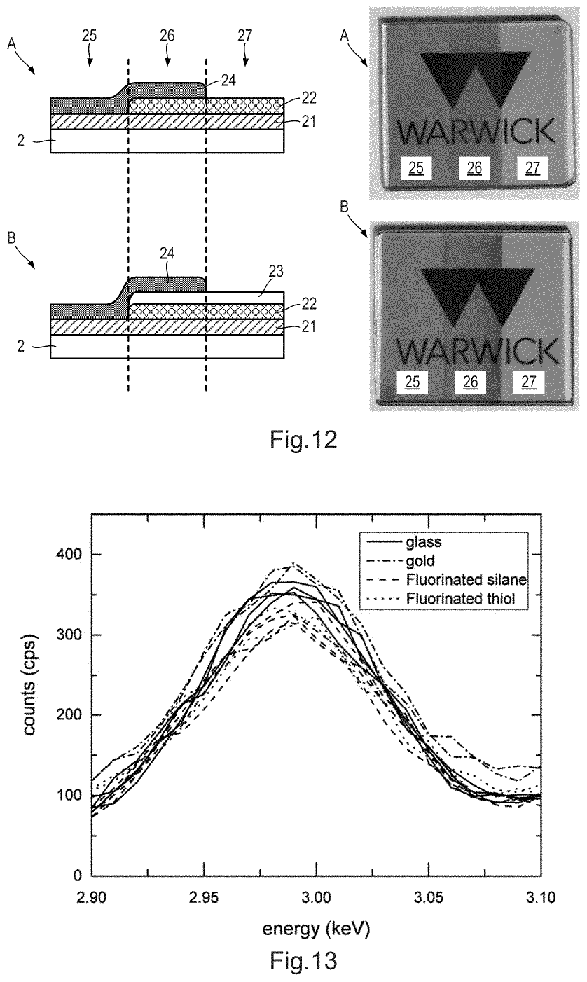

Referring also to FIG. 12, photographs are shown of a pair of samples, A and B, along with schematic cross sections of both samples.

Samples A and B both included a glass substrate 2, functionalized with a mixed monolayer 21 formed of [(3-mercaptopropyl) trimethoxysilane (MPTMS) and (3-aminopropyl)trimethoxysilane (APTMS)] and deposited from the vapour phase. The rightmost two-thirds of samples A and B were coated with a 11 nm thick layer of evaporated gold 22. The gold layer 22 was deposited using a conventional, physical mask. The whole sample B was then dipped in a 1 mM ethanol solution of 3,3,4,4,5,5,6,6,7,7,8,8,8-tridecafluoro-1-octanethiol forming a densely packed monolayer 23 of 3,3,4,4,5,5,6,6,7,7,8,8,8-tridecafluoro-1-octanethiol on the gold layer 22. Finally, the leftmost two-thirds of both samples A and B was coated with a 12 nm thick layer of evaporated silver 24. The silver layer 24 was deposited using a conventional, physical mask. In this way, both samples A and B were divided into the three stripes 25, 26, 27, as observed in the photographs.

Referring also to FIG. 13, EDXS spectra are shown which correspond to silver metallic layers 10 deposited onto substrates 2 having different surface energies. Fluorinated silane is a densely packed monolayer of 1H,1H,2H,2H-perfluorooctyldimethylchlorosilane deposited on a glass slide from the vapour at low pressure. Fluorinated thiol is a densely packed monolayer of 3,3,4,4,5,5,6,6,7,7,8,8,8-Tridecafluoro-1-octanethiol deposited on a gold layer from a 1 mM ethanol solution. Metallic layers 10 of 15 nm thick silver were deposited on glass surfaces 1, and on glass surfaces 1 coated with a monolayer of fluorinated silane. Metallic layers 10 of 12 nm thick silver were deposited on gold surfaces 1, and on gold surfaces 1 coated with a monolayer of fluorinated thiol.

It may be observed from FIGS. 12 and 13 that a fluorinated monolayer was not sufficient to block deposition of silver. For example, the appearance of samples A and B in the photographs of FIG. 12 is essentially identical. With the intention of testing the generality of this finding, a monolayer of the thiol analogue of FTS; 3,3,4,4,5,5,6,6,7,7,8,8,8-tridecafluoro-1-octanethiol (fluorinated thiol) was prepared on an ultra-smooth semi-transparent gold film, using a deposition method that is known to result in a compact monolayer. For the thiol analogue, it was again observed that a monolayer was not sufficient to block condensation of silver.

Referring in particular to FIG. 13, it may be observed from EDXS analysis that the amount of silver deposited onto substrates with a monolayer of the monochlorosilane and the thiol analogue of FTS is approximately the same as was deposited on the substrates without a fluorinated layer 5. Without wishing to be bound by theory, one interpretation of these findings is that the silver may be initially adsorbed at the surface, and diffuses sub-surface before either being ejected back into the vapor phase, or nucleating. Whilst the extent of this sub-surface diffusion would be expected to depend on the composition and structure of the fluorinated layer 5 (the latter depending on the deposition method), and also on the metal deposition rate, the inventors have observed that in practice a fluorinated layer 5 in the form of FTS with a thickness of about 10 nm is typically needed to achieve selective deposition of copper or silver, and about 20-30 nm is typically needed to achieve selective deposition of gold. In general, the required minimum (sufficient) thickness of the fluorinated layer 5 may depend on a variety of factors such as, for example, the metal or metals to be used, the deposition rate for evaporation, the specific materials of the substrate 2, fluorinated layer 5, the adhesion layer 3 (if present), and so forth. Procedures for determining a sufficient thickness of the fluorinated layer 5 are explained hereinafter.

Although the preceding observations relate to FTS and silver in particular, similar effects are expected for other fluorinated polymers/molecules and for copper and/or gold.

As a demonstration of selective silver deposition over a larger, macroscopic area, a 3.2 cm² glass slide was coated with a 10 to 20 nm thick fluorinated layer 5 of FTS by spin coating from 1:3 v/v silane/toluene solution.

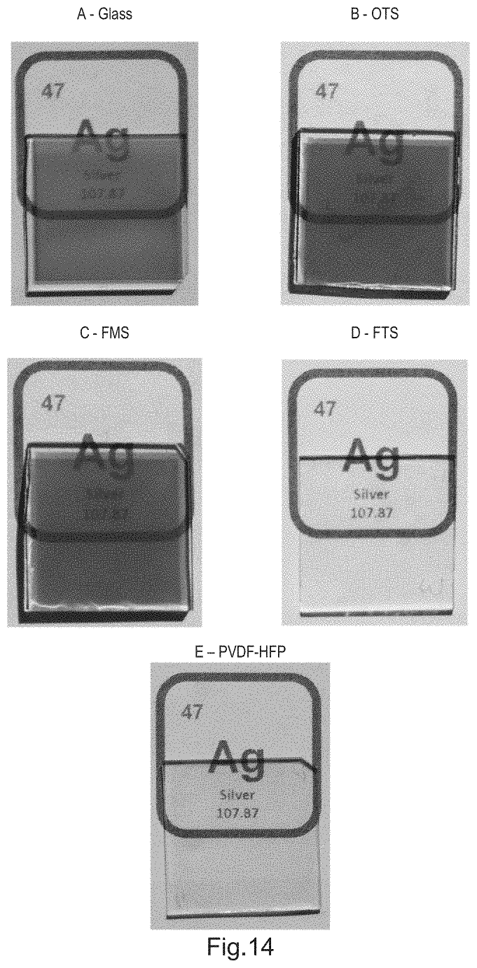

Referring also to FIGS. 14A to 14E, photographs are shown of glass samples coated with a variety of different layers, and then coated with a nominally 15 nm thick (i.e. this is the thickness measured using a quartz-crystal micro-balance) silver layer. FIG. 14A shows an untreated 3.2 cm² glass slide evaporation coated with silver. FIG. 14B shows a 3.2 cm² glass slide coated with octyltrichlorosilane (OTS) and evaporation coated with silver over the OTS layer. FIG. 14C shows a 3.2 cm² glass slide coated with FMS and evaporation coated with silver over the FMS layer. FIG. 14D shows a 3.2 cm² glass slide coated with FTS and evaporation coated with silver over the FTS layer. FIG. 14E shows a 3.2 cm² glass slide coated with poly(vinylidene fluoride-co-hexafluoropropylene) (PVDF-HFP, (—CH₂CF₂-)ₓ[—CF₂CF(CF₃)—]_{y}) and evaporation coated with silver over the PVDF-HFP layer. Structures and surface energies for the coating molecules corresponding to FIGS. 14A to 14E are set out in Table 1.

TABLE 1

| | glass | OTS | FMS | FTS | PVDF-HFP |
|---|---|---|---|---|---|
| Molecule | None | 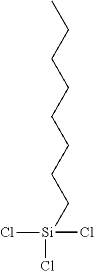 | 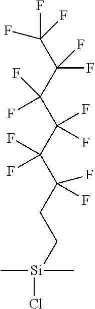 | 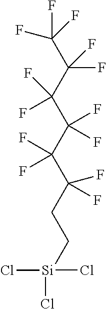 | 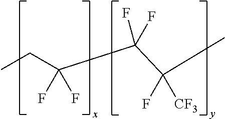 |
| Surface | — | 27 | 20 | 13 | 30 |
| energy | | | | | |
| (mJ m⁻²) | | | | | |

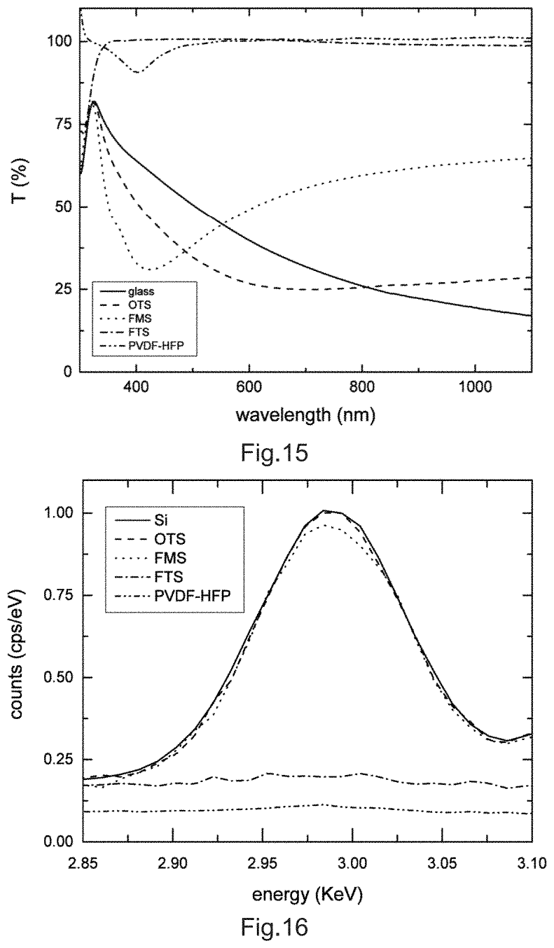

Referring also to FIG. 15, transmittance data as a function of wavelength are plotted for the five samples shown in FIGS. 14A through 14E.

The variations in transmittance illustrate the variations in the quantity of silver which actually adhered to the samples shown in FIGS. 14A through 14E. It may be observed that the samples coated with FTS and PVDF-HFP exhibited significantly higher transmittance than the untreated glass or the samples coated with OTS or FMS.

Referring also to FIG. 16, normalised EDXS spectra are shown for the silver peak of nominally 15 nm thick silver layers deposited onto silicon substrates coated in the same way as the five samples shown in FIGS. 14A through 14E.

It may be observed that the untreated silicon and the samples coated with OTS or FMS exhibit a strong peak corresponding to silver (analogous to samples shown in FIGS. 14A, 14B and 14C), whereas the samples coated with FTS and PVDF-HFP do not (analogous to samples shown in FIGS. 14D and 14E).

It may be observed from the EDXS data plotted in FIG. 16 and the photographs in FIGS. 14A through 14E that there is no significant metal deposition over the entire areas of the sample coated with FTS. Conversely, silver is observed to deposit onto films of the hydrocarbon analogue; octyltrichlorosilane (OTS) of comparable thickness (>50 nm), which is considered to indicate that the silane moiety is not critical in enabling selective deposition. Instead, it appears that the fluorocarbon backbone may be the relevant feature of the molecule. This interpretation is supported by the demonstration of selective deposition using the entirely different fluorinated polymer; poly(vinylidene fluoride-co-hexafluoropropylene) (PVDF-HFP, (—CH₂CF₂-)ₓ[—CF₂CF(CF₃)—]_{y}) (see FIG. 14E), which has no silane functionality.

In order to deposit optically thin metallic layers 10 having a well-defined thickness, it is preferable to use a relatively low metal deposition rate (˜1 Angstrom per second). Increasing the deposition rate by a factor of about 5 to 6 (and the metallic layer 10 thickness to ˜70 nm) was observed to result in a greater frequency of metallic nanoparticle 13 formation at and around the edges of the microcontact printed regions of FTS forming the fluorinated layer 5. However, the central areas of the fluorinated layer 5 where the FTS was thicker were still observed to remain essentially free of metal.

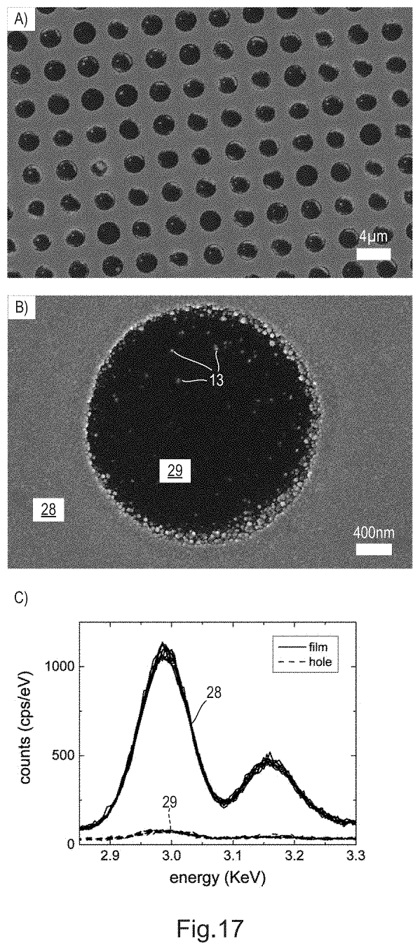

For example, referring also to FIGS. 17A and 17B, SEM images are presented of a sample made by evaporating a 70 nm thick silver metallic layer 10 with a high deposition rate (5-6 Angstroms per second) on a MoO₃₋ₓ adhesion layer 3 evaporated on a glass substrate 2. A fluorinated layer 5 in the form of FTS was used to define the apertures 12.

Referring also to FIG. 17C, EDXS spectra 28, 29 are shown of the peak corresponding to silver, acquired either from the apertures 12 or from the continuous 70 nm thick silver metallic layer 10.

Increasing the deposition rate requires an increase in the temperature of the metal source, which inevitably increases the mean kinetic energy of the incident metal atoms 11, and thus the propensity of the metal atoms 10 to penetrate and/or diffuse into/through the fluorinated layer 5. Consequently, to accommodate higher metal deposition rates for selective metal deposition, it may be preferable to increase the thickness of the fluorinated layer 5 to compensate for increased incident energies of metal atoms 11.

### Experimental Data for Copper Deposition

The methods of the present specification are not limited to silver, and samples were also prepared using copper.

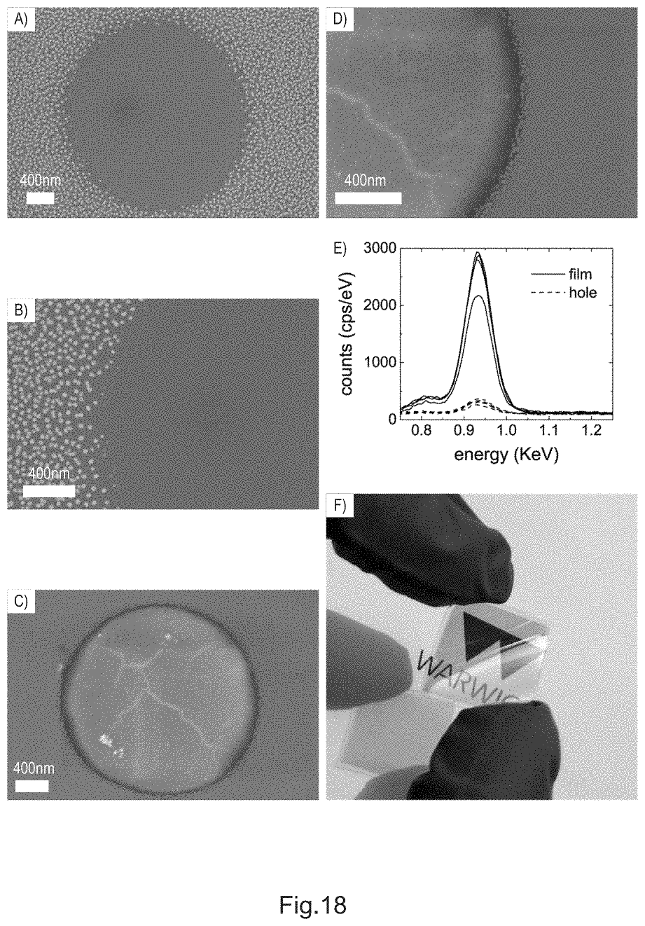

Referring also to FIGS. 18A and 18B, SEM images are shown of a 10 nm thick copper metallic layer 10 deposited on a MoO₃₋ₓ adhesion layer 3 on a glass substrate 2. Patterning was provided by a fluorinated layer 5 in the form of microcontact printed FTS circles. The scale bar represents 400 nm.

Referring also to FIGS. 18C and 18D, SEM images are shown of a 15 nm copper metallic layer 10 evaporated over a PEI layer spin coated onto a PET substrate, then microcontact printed with FTS circles. The scale bar represents 400 nm.

Referring also to FIG. 18E, copper peak EDXS spectra are shown which were acquired either from the apertures 12 or from the continuous copper metallic layer 10 deposited on the PEI adhesion layer 3.

Referring also to FIG. 18F, a photograph is shown of a 3.2 cm² copper metallic layer evaporated on a flexible substrate formed from a PEI adhesion layer 3 coated over a PET substrate 2. The copper metallic layer 10 was micropatterned using a fluorinated layer 5 of microcontact printed FTS.

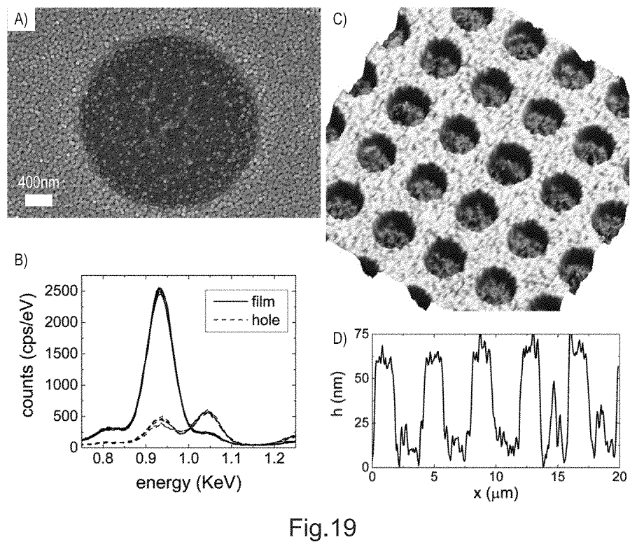

Referring also to FIG. 19A, an SEM image is shown of an aperture 12 in a copper metallic layer 10 with nominal thickness 85 nm, supported on a MoO₃₋ₓ adhesion layer 3 coated over a glass substrate 2, with patterning provided by a fluorinated layer 5 formed of microcontact printed FTS.

Referring also to FIG. 19B, the copper peak from EDXS spectra acquired from either the apertures 12 or the copper metallic film 10 shown in FIG. 19A.

Referring also to FIG. 19C, an AFM scan of the copper metallic film 10 shown in FIG. 19A is shown, and in FIG. 19D a height profile along a line of apertures 12 is shown.

It may be observed that the methods of the present specification are equally effective for copper. However, copper does not bind strongly to MoO₃₋ₓ adhesion layers 3, as shown in FIGS. 18A, 18B and FIG. 19. In particular, the copper tends not to grow as a smooth film on the MoO₃₋ₓ surface. A solution processed PEI layer was found to be more effective as an adhesion layer 3 for copper (see FIGS. 18C through 18F).

Referring again to FIGS. 3J and 3K, and also to FIGS. 18C to 18F, it may be observed that the methods of the present specification translate to PET substrates 2 with either MoO₃₋ₓ or PEI providing an adhesion layer 3 for silver, and PEI providing an adhesion layer for copper. In this way, the methods of the present specification may be advantageously applied to flexible substrates 2.

For some applications it may be desired to remove the thin fluorinated layer 5 following deposition of the metallic layer 10. When the fluorinated layer 5 is, for example FTS, removal of the fluorinated layer 5 without removing the metallic layer 10 may be achieved by a simple rinsing step using 0.2M tetrabutylammonium fluoride/tetrahydrofuran solution, followed by rinsing with water. The rinsing with water dissolved the MoO₃₋ₓ adhesion layer 3 where it is not protected by the metallic layer 10. The removal step leaves apertures 12 of well-defined depth equal to the sum of the MoO₃₋ₓ and silver layer thickness.

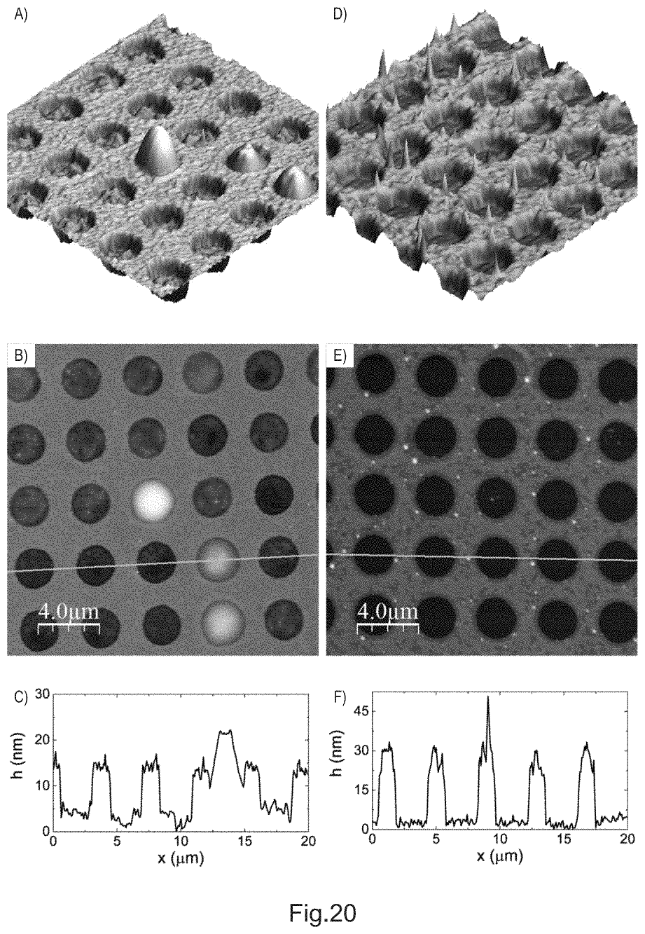

For example, referring also to FIG. 20, AFM scans are shown of a patterned, nominally 15 nm thick silver metallic layer 10 after deposition of the metallic layer 10 in FIG. 20A, and after rinsing with tetrabutylammonium fluoride/tetrahydrofuran and water in FIG. 20D. FIGS. 20B and 20E show top-down views of the AFM scans in FIGS. 20A and 20D respectively, with contrast indicating the relative heights. FIGS. 20C and 20F show height profiles along the lines drawn in FIGS. 20B and 20E respectively.

### Selective Deposition of Gold

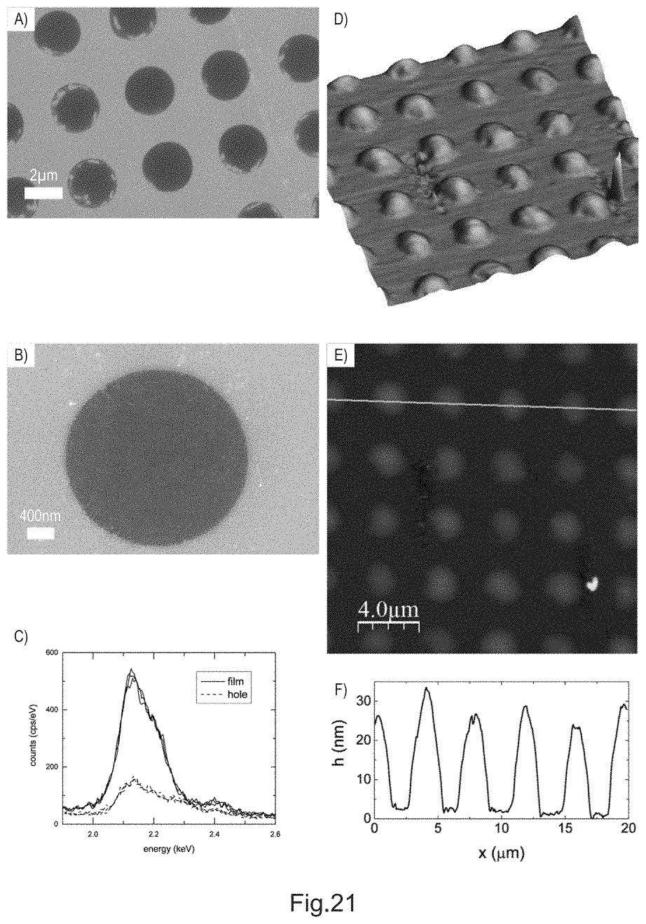

Referring also to FIG. 21, experimental data are shown for selective deposition of gold.

Referring in particular to FIGS. 21A and 21B, SEM images are shown of a nominally nm thick gold layer evaporated over a glass substrate coated with MoO₃ and printed with FTS circles.

Referring in particular to FIG. 21C, gold peak EDXS spectra are shown which were acquired either from the apertures 12 or from the gold metallic layer 10.

Referring in particular to FIG. 21D, an AFM scan is shown of the printed FTS circles providing the fluorinated layer 5, which may be observed as the bumps in FIG. 21D.

Referring in particular to FIG. 21E, a top view of the AFM scan shown in FIG. 21D is shown.

Referring in particular to FIG. 21F, a height profile is shown along a line indicated in FIG. 21E.

It may be observed from the EDXS spectra (FIG. 21C) that the amount of gold deposited on or over the regions corresponding to the FTS circles is greater than for copper or silver. Nonetheless, the deposition is still observed to be selective, as the gold EDXS spectrum peak is several times greater for the metallic film 10 than for the aperture 12. It may be observed that the thickness of fluorinated layer 5 for selective deposition of gold is more than 10 nm, and more in the region of 20 to 30 nm. The amount of gold deposited in the apertures 12 may be further reduced by further increasing the thickness of the fluorinated layer 5. It is believed that the larger mass and/or reduced reactivity of gold, compared to copper or silver, may be a factor in the larger minimum thickness of the fluorinated layer 5 for gold deposition.

### Material Properties Likely to Affect Suitability for Selective Metal Deposition

Without wishing to be bound by theory, the physical and chemical properties presently thought to be connected with selective deposition of copper, silver and/or gold shall be briefly discussed.

The interaction between moderately reactive metals like silver, copper and gold and closed shell covalently bonded saturated hydrocarbons and fluorocarbons is generally very weak. Consequently, when these metals condense on a surface with these functionality the large cohesive energy between metal atoms drives the formation of metal clusters, which coalesce to form a continuous film at high nominal metal coverage. The size of the metal clusters is known to depend on the rate of deposition of the metal and the ease with metal atoms can diffuse over the surface of the substrate. Conversely the factors affecting the process of spontaneous desorption of metal atoms from soft surfaces are poorly understood. It is evident from Table 1 that there is no correlation between the surface energy of the fluorinated hydrocarbon layer and the extent of Ag deposition, since the surface energy of the PVDF-HFP film and OTS films are comparable, but metal is only deposited on the latter. What is distinct about highly fluorinated organic molecules and polymers, as compared to their hydrocarbon analogues is the exceptional weakness of the intermolecular attractive forces (or cohesive energies), which stems from the low polarizability and high ionization potential of the carbon-fluorine bond combined with the relatively large intermolecular separation resulting from steric repulsion between fluorine atoms. Consequently, fluorinated molecules exhibit exceptionally low boiling points, (e.g. perfluorohexane at 57° C. vs. hexane at 69° C.) together with low surface energies compared to their hydrocarbon counterparts (OTS (27.1±0.5 mJ·m⁻²) vs. FTS (13.2±0.9 mJ·m⁻²) Table 1). It follows that the weaker intermolecular interactions, together with the metal-molecule interaction would enable more facile diffusion of copper and silver atoms into and out of the surface of a highly fluorinated hydrocarbon film, reducing the likelihood that metal atoms become trapped in the matrix and seed metal nucleation.

Consequently, because of the hereinbefore mentioned properties of fluorocarbons, it is expected that the methods of the present specification should be applicable to copper, silver and/or gold in combination with a wide range of fluorinated molecules or polymers which have not been explicitly demonstrated.

Using the methods of the present specification, selective deposition of patterned or unpatterned (i.e. not ordered) copper, silver and/or gold thin films by simple thermal evaporation is possible. This may enable the fabrication of dense arrays of features with dimensions spanning the range from nanometre to centimetre scales. Furthermore, the methods of the present specification may be scaled to large areas. Using the methods of the present specification, the shape and dimensions of the features patterned into metallic layers 10 are limited only by the printing method used.

The experimental data indicates that the two key elements to suppressing metal deposition are the presence of the fluorinated layer 5 and a sufficient thickness of said fluorinated layer 5. The necessary thickness of the fluorinated layer 5 may depend on the fluorinated compound(s) used, the deposition method and the rate of metal deposition. The minimum thickness for selective deposition of copper or silver has been observed to be of the order of ≥10 nm. The minimum thickness for selective deposition of gold has been observed to be of the order of ≥20-30 nm The low thickness of the fluorinated layer 5 means that it can be either left in-situ, or simply rinsed away following deposition of the metallic layer 10, depending on the application.

A sufficient thickness of the fluorinated layer 5 is expected to depend upon:
1. The specific material or materials used to form the fluorinated layer 5.
2. The metal or metals, selected from the group containing copper, silver and gold, which are to be deposited.
3. The deposition rate. The deposition rate is believed to be a factor because a greater deposition rate typically corresponds to greater energy of incident metal atoms on the fluorinated layer 5.
4. The material providing the surface 1 of the substrate 2, and/or the alternative surface 4 of the adhesion layer 3 (when used).
5. The application for which the metallic layers 10 produced are intended.
6. The final thickness to which the metallic layer 10 is deposited on the regions not covered by the fluorinated layer 5.

The preceding list is not intended to be exhaustive. The methods of the present application may be optimised for specific materials, evaporated metals and a given rate of deposition using simple procedures.

For example, a metallic layer 10 may be deposited for its optical properties in an architectural application. In this context, it may be required that the metallic layer 10 should be optically opaque and should cover a fraction of 20% of the surface 1 of a glass substrate 2. This would theoretically reduce the transmittance of the coated substrate 2 by the same factor of 20% as the metallic layer 10 will reflect light from the areas where it is present. However, if the fluorinated layer 5 is not sufficiently thick, the transmittance will be reduced by more than the desired 20%, because more than 20% of the glass substrate 2 will be covered by an optically thick metallic layer 10.

The minimum thickness of fluorinated layer 5 to achieve selective deposition may be simply determined by increasing the thickness of the fluorinated layer 5 over the course of multiple test samples, depositing a metallic layer 10 on each test sample, and measuring the corresponding transmittance values. Once the transmittance reaches the desired 20% reduction, or to within a certain tolerance such as, for example, ±1%, ±5%, ±10%, ±15% and so forth, the minimum sufficient thickness of fluorinated layer 5 for the particular application, deposition rate and combination of materials has been found.

Determining a sufficient thickness of fluorinated layer 5 is not limited to optical transmittance of the selectively deposited metallic layer 10. Any specified property or characteristic of the metallic film 10 may be used in a similar trial and error method to determine a minimum sufficient thickness of the fluorinated layer 5. Examples of suitable properties or characteristics of the metallic film 10 include, but are not limited to, the sheet resistance of the apertures 12, a ratio of sheet resistance of the metallic layer 10 to the apertures 12, far field transmittance and/or reflectance of the metallic layer 10 or coated substrate 2, population density of isolated metallic nanoparticles 13 in the apertures 12 (e.g. measured by SEM imaging), relative intensity of an EDXS metal peak (e.g. copper silver or gold) in areas covered by the fluorinated layer 5 and areas not covered by the fluorinated layer 5, and so forth.

### Methodology for Experimental Samples

### Master Fabrication

A silicon master having an array of holes was produced by standard photolithography: a clean silicon wafer was spin coated with a uniform layer of photoresist (S1818, 300 rpm for 5 s and 4000 rpm for 20 s); after baking at 115° C. it was exposed to ultraviolet light (130 mJ/cm²) under a chromium/quartz mask and developed in MF319 developer for 35 s. The patterned photoresist layer was used as a mask for the etching process and then was removed. The final structure was an array of holes having a diameter d˜2.5 um, spacing s˜4 um and height h˜1.5 μm. The silicon master was coated with a Trichloro(1H,1H,2H,2H-perfluorooctyl)silane layer deposited from the vapour phase at a low pressure to help replica detachment. This first step based on photolithography was performed just once and then the silicon master could be replicated several times.

### Microcontact Printing (PDMS+Printing)

The silicon master was replicated with polydimethylsiloxane (PDMS, Sylgard 184) to produce the stamp 6 for the microcontact printing procedure. Base and curing agent were mixed (10:1 w/w), degassed and poured onto the master. After curing at ˜80° C. for ˜1 h the polymerised stamp 6 was gently peeled off the master.

Before printing, the substrates were cleaned and coated with adhesion layers promoting metal adhesion:
a) 10 nm MoO₃₋ₓ adhesion layers 3 evaporated onto glass or PET substrates 2 at 0.3 Å/s or
b) 0.3% w/v PEI/water solution spin coated onto PET substrates (5000 rpm for 60 s, then annealed at 100° C. for 20 minutes).

The PDMS stamp 6 was inked with 1 mM FTS/toluene solution for 1 minute, then thoroughly dried with nitrogen and put in contact with the substrate for 40 s. Laboratory grade toluene was used because it contains a small amount of water, which allows the FTS to polymerise in solution so that a thick layer of FTS is printed (10-30 nm, depending what is needed) rather than a monolayer.

### Metal Evaporation

Silver, copper or gold metallic films in the thickness range of 15-85 nm were evaporated at 1 Å/s (unless otherwise stated), directly onto the substrates printed with the fluorinated layers 5 using the PDMS stamp 6.

### Washing

To remove the fluorinated layers 5 formed of FTS, the samples were coated with a 0.2 M tetrabutylammonium fluoride/tetrahydrofuran solution and left for a few seconds, then the sample was spun at around 2000-3000 rpm and whilst a few droplets of deionised water were applied to the surface during spinning. This procedure is specific to the case of when the fluorinated layer 5 is made from cross-linked chloro or methoxy silane. These compounds cross-link to form a siloxane polymer Si—O—Si and the tetrabutylammonium fluoride breaks these bonds, enabling the dissolution of the polymer. When different materials are used for the fluorinated layer 5, different solutions and/or solvents may be needed.

The application of water may result in the removal of the MoO3 adhesion layer 3 in areas which are not covered by the metallic layer 10, as explained hereinbefore (see FIG. 2G).

An alternative washing process would be to dip the sample in the fluoride solution and then dip the in the sample water.

### Modifications

It will be appreciated that many modifications may be made to the embodiments hereinbefore described. Such modifications may involve equivalent and other features which are already known in production of patterned metallic layers, and which may be used instead of, or in addition to, features already described herein. Features of one embodiment may be replaced or supplemented by features of another embodiment.

Although samples have been described which included adhesion layers 3, the use of adhesion layers is not essential. When a surface 1 has a relatively high condensation coefficient, for example C>0.9, an adhesion layer 3 may be omitted. Similarly, when a relatively thick metallic layer 10 is required, for example an optically opaque metallic layer 10, an adhesion layer 3 may also be omitted. This is because even if metal atoms 11 would tend to form isolated islands/particles on a native surface 1 for a thin film, as the thickness is increased the isolated islands/particles will coalesce. When thin, for example optically transparent, metallic layers 10 are required, adhesion layers 3 may help to ensure development of a continuous, thin metallic layer 10.

Although examples have been described in which the fluorinated layer 5 was deposited according to a precise pattern forming a negative image of a desired metallic layer 10, this is not always necessary. For many applications, the fluorinated layer 5 does not need to be highly structured or intentionally patterned.

In some architectural applications and/or optical applications it may be desired to modify a sheet of transparent material, such as glass, in order to obtain tailored transmittance and/or reflectance at a given wavelength. Transparent materials treated in this way may provide low emissivity glass. As specific in-plane connectivity of the metallic layer 10 is not required in order to obtain tailored transmittance and/or reflectance. It may be sufficient to selectively deposit a metallic layer 10 to cover a predetermined fraction of the surface.

Referring also to FIGS. 22A to 22G, an example of selective deposition using a randomised fluorinated layer 5 is shown. The method is essentially similar to that shown in FIGS. 2A to 2G, and identical processing steps will not be described again.

The main difference is that the fluorinated layer 5 is deposited as an unpatterned fluorinated layer 5′. An unpatterned fluorinated layer 5 may be deposited in a number of ways, for example spray deposition or printing.

In the example shown in FIGS. 22A to 22G, spray deposition is shown. A nozzle 30 sprays droplets 31 of ink 9 or another substance suitable for forming the unpatterned fluorinated layer 5′. The droplets 31 may be applied to the surface until a fraction of the surface covered by the unpatterned fluorinated layer 5′ is equal or approximately equal to a predetermined fraction. The droplets 31 produced by the nozzle 30 will have a measureable and typically repeatable size distribution, and the necessary duration of spraying needed to obtain a given predetermined area fraction of unpatterned fluorinated layer 5′ may be readily determined from calibration experiments. The predetermined area fraction may be determined based on a desired reflectance and/or transmittance of the metallic layer 10, for example, the predetermined area fraction for the unpatterned fluorinated layer 5′ should be the complement of the desired area fraction of the metallic layer 10.

Alternatively, the fluorinated layer 5 may be deposited by dewetting of a continuous layer, for example a continuous layer of ink 9, to form a fluorinated layer 5 in the form of randomly distributed islands. The randomly distributed islands may be cured and/or allowed to dry to form the unpatterned fluorinated layer 5. A continuous layer for dewetting, for example a continuous layer of ink 9, may be formed using any suitable method such as, for example, printing, spraying, rolling and so forth. Dewetting may be performed by heating the continuous layer, by exposing the continuous layer to a solvent, and so forth.

Although claims have been formulated in this application to particular combinations of features, it should be understood that the scope of the disclosure of the present invention also includes any novel features or any novel combination of features disclosed herein either explicitly or implicitly or any generalization thereof, whether or not it relates to the same invention as presently claimed in any claim and whether or not it mitigates any or all of the same technical problems as does the present invention. The applicant hereby gives notice that new claims may be formulated to such features and/or combinations of such features during the prosecution of the present application or of any further application derived therefrom.

1. A method of selectively depositing a metallic layer comprising one or more of copper, silver and gold, the method comprising:
depositing a fluorinated layer over a surface, the fluorinated layer having a thickness sufficient to substantially prevent deposition of the copper, silver and/or gold between the fluorinated layer and the surface during a subsequent evaporation step using a given deposition rate; and
forming the metallic layer by evaporating, at the given deposition rate, the copper, silver and/or gold over the surface and the fluorinated layer, wherein the copper, silver and/or gold preferentially adhere to portions of the surface not covered by the fluorinated layer.

2. A method according to claim 1, wherein the fluorinated layer is deposited as a negative image of a pattern, such that the metallic layer is selectively deposited according to the pattern.

3. A method according to claim 1, wherein the fluorinated layer is deposited by applying droplets of a fluorinated compound to the surface until a fraction of the surface covered by the fluorinated layer is equal or approximately equal to a predetermined fraction.

4. A method according to claim 1, further comprising a washing process to remove the fluorinated layer without removing the metallic layer.

5. A method according to claim 1, wherein the surface corresponds to a substrate which is pre-coated with an adhesion layer, and wherein the fluorinated layer and metallic layer are deposited over the adhesion layer.

6. A method according to claim 1, wherein the surface corresponds to a substrate, and the method further comprises coating the surface with an adhesion layer,
wherein the fluorinated layer and metallic layer are deposited over the adhesion layer.

7. (canceled)

8. (canceled)

9. A method according to claim 1, wherein depositing the fluorinated layer comprises printing, spray-deposition or dip-coating.

10. A method according to claim 1, comprising forming the metallic layer to an optically transparent thickness.

11. A method according to claim 1, comprising forming the metallic layer to an optically opaque thickness.

12. A method according to claim 1, wherein the metallic layer comprises a transparent mesh.

13. A metallic layer comprising one or more of copper, silver and gold selectively deposited on a surface, the metallic layer formed by:
depositing a fluorinated layer over the surface, the fluorinated layer having a thickness sufficient to substantially prevent deposition of the copper, silver and/or gold between the fluorinated layer and the surface during a subsequent evaporation step using a given deposition rate; and
forming the metallic layer by evaporating, at the given deposition rate, the copper, silver and/or gold over the surface and the fluorinated layer, wherein the copper, silver and/or gold preferentially adhere to portions of the surface not covered by the fluorinated layer.

14. A metallic layer according to claim 13, wherein forming the metallic layer comprises depositing the fluorinated layer as a negative image of a pattern, and wherein the metallic layer is deposited according to the pattern.

15. A metallic layer according to claim 13, wherein forming the metallic layer comprises depositing the fluorinated layer by applying droplets of a fluorinated compound to the surface until a fraction of the surface covered by the fluorinated layer is equal or approximately equal to a predetermined fraction, wherein the fraction of the surface covered by the metallic layer is approximately complement of the predetermined fraction.

16. (canceled)

17. A metallic layer comprising one or more of copper, silver and gold deposited on a surface, wherein a fluorinated layer covers those parts of the surface from which the metallic layer is absent.

18. A metallic layer according to claim 13, wherein the surface is coated with an adhesion layer, and the metallic layer is deposited over the adhesion layer.

19. (canceled)

20. (canceled)

21. A metallic layer according to claim 13, wherein the metallic layer has an optically transparent thickness.

22. A metallic layer according to claim 13, wherein the metallic layer has an optically opaque thickness.

23. A metallic layer according to claim 13, wherein the metallic layer comprises a transparent mesh.

24. An electronic device comprising a metallic layer according to claim 13.

25. A photovoltaic device, organic photovoltaic device, touch panel, touchscreen panel, light emitting device, organic light emitting device or sensor, comprising a metallic layer according to claim 13.
